(19) United States
(12) Patent Application Publication
(10) Pub. No.: US 2026/0334085 A1
(43) Pub. Date: Oct. 22, 2026

(54) PIEZOELECTRIC DEVICE HAVING PIEZOELECTRIC STRUCTURE DISPOSED BETWEEN PATTERNED CONDUCTIVE STRUCTURES

(71) Applicant: Taiwan Semiconductor Manufacturing Company, Ltd., Hsinchu (TW)

(72) Inventors: Ching-Hui Lin, Taichung City (TW); Yi-Hsien Chang, Shetou Township (TW); Chun-Ren Cheng, Hsin-Chu City (TW); Shih-Fen Huang, Jhubei (TW); Fu-Chun Huang, Zhubei City (TW); Chao-Hung Chu, Keelung City (TW); Po-Chen Yeh, New Taipei City (TW)

(21) Appl. No.: 19/721,568

(22) Filed: Jun. 26, 2026

Related U.S. Application Data
(62) Division of application No. 18/321,268, filed on May 22, 2023.

(51) Int. Cl. H10N 30/87; H10N 30/057; H10N 30/063; H10N 30/072; H10N 30/50

(52) U.S. Cl. CPC H10N 30/872; H10N 30/057; H10N 30/063; H10N 30/072; H10N 30/50

(57) ABSTRACT

Various embodiments of the present disclosure are directed towards a piezoelectric device including a piezoelectric structure over a substrate. A first conductive structure is disposed on a lower surface of the piezoelectric structure. The first conductive structure includes one or more first movable elements directly contacting the piezoelectric structure. A second conductive structure is disposed on an upper surface of the piezoelectric structure. The second conductive structure includes one or more second movable elements directly contacting the piezoelectric structure. The one or more second movable elements directly overlie the one or more first movable elements.

### REFERENCE TO RELATED APPLICATION

This Application is a Divisional of U.S. application Ser. No. 18/321,268, filed on May 22, 2023, the contents of which are hereby incorporated by reference in their entirety.

### BACKGROUND

Piezoelectric devices (e.g., piezoelectric actuators, piezoelectric sensors, etc.) are used in many modern-day electronic devices (e.g., automotive sensors/actuators, aerospace sensors/actuators, speakers, micro-speakers, microphones, smart phones, hearing aids, etc.). The piezoelectric devices can be used to translate between movement of a physical part in a system and an electrical signal. The physical movement generated or observed by a piezoelectric device can be used to transmit or receive different kinds of signals for mechanical systems, audio systems, and/or optical systems.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C illustrate various views of some embodiments of a semiconductor structure including a piezoelectric device comprising a piezoelectric structure disposed between patterned conductive structures.

FIGS. 2A-2C and 3A-3C illustrate various views of some other embodiments of the semiconductor structure of FIG. 1A.

FIGS. 4A-4C illustrate various views of some other embodiments of a semiconductor structure including a piezoelectric device comprising a piezoelectric structure disposed between patterned conductive structures.

FIG. 5A illustrates a cross-sectional view of other embodiments of the semiconductor structure of FIG. 1A in which the piezoelectric structure has a continuous thickness.

FIG. 5B illustrates a cross-sectional view of other embodiments of the semiconductor structure of FIG. 4A in which the piezoelectric structure has a continuous thickness.

FIG. 5C illustrates a cross-sectional view of some other embodiments of the semiconductor structure of FIG. 1A.

FIG. 6 illustrates a cross-sectional view of some embodiments of a piezoelectric device coupled to a transistor.

FIGS. 7A-23 illustrate various views of some embodiments of a first method of forming a piezoelectric device comprising a piezoelectric structure disposed between patterned conductive structures.

FIG. 24 illustrates a flow diagram of some embodiments of a first method of forming a piezoelectric device comprising a piezoelectric structure disposed between patterned conductive structures.

FIGS. 25A-41 illustrate various views of some embodiments of a second method of forming a piezoelectric device comprising a piezoelectric structure disposed between patterned conductive structures.

FIG. 42 illustrates a flow diagram of some embodiments of a second method of forming a piezoelectric device comprising a piezoelectric structure disposed between patterned conductive structures.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A piezoelectric device (e.g., a piezoelectric transducer) may include a first electrode layer, a second electrode layer, and a piezoelectric structure. The first and second electrode layers are disposed on the piezoelectric structure and are configured to convert electrical energy to mechanical energy or vice versa. For example, a voltage may be applied between the first and second electrodes to deflect or deform the piezoelectric structure, thereby generating sound waves. Further, deflection of the piezoelectric structure in response to external stimuli (e.g., sound waves) may be detected by the first and second electrode layers and may be converted to an electrical signal.

The first and second electrode layers of the piezoelectric device may be formed in a number of different ways depending on an operating mode of the piezoelectric device. For example, the first electrode layer may be formed on a bottom surface of the piezoelectric structure and the second electrode layer may be formed on a top surface of the piezoelectric structure. In such instances, the first and second electrode layers define a first plate and a second plate on opposing surfaces of the piezoelectric structure where the piezoelectric device may operate in a first operating mode (e.g., a d31 mode). In the first operating mode, a bias voltage is applied across the first and second electrode layers, thereby generating an electric field having a first direction that is orthogonal to the top surface of the piezoelectric structure. As a result, a thickness of the piezoelectric structure changes (e.g., increases in a center region) and the top surface of the piezoelectric structure moves upward in the first direction. However, in such a configuration a maximum deflection and/or compression of the piezoelectric structure during operation of the piezoelectric device is relatively low, thereby reducing a sensitivity and overall performance of the piezoelectric device.

In another example, the first and second electrode layers are both formed on a top surface of the piezoelectric structure and respectively comprise elongated electrode segments. The elongated electrode segments of the first electrode layer are spaced alternatingly with the elongated electrode segments of the second electrode layer such that the piezoelectric device may operate in a second operating mode (e.g., a d33 mode). In the second operating mode, a bias voltage is applied across the first and second electrode layers, thereby generating an electric field having a first direction that is parallel to the top surface of the piezoelectric structure. As a result, a thickness of the piezoelectric structure changes (e.g., decreases in a center region) and the top surface of the piezoelectric structure moves downward in a second direction orthogonal to the first direction. Due to a layout of the elongated electrode segments of the first and second electrode layers, a maximum deflection and/or compression of the piezoelectric structure is greater (e.g., at least two times greater) than that of a piezoelectric device configured to operation in the first mode. However, in such configurations, during fabrication the first and second electrode layers are patterned on the piezoelectric structure to form the elongated electrode segments. A patterning process is performed on a carrier substrate to form a cavity. Subsequently, an alignment process is utilized to bond the piezoelectric structure to the carrier substrate such that the cavity is disposed under the elongated electrode segments of the first and second electrode layers. This, in part, increases fabrication complexity and may result in misalignment between the cavity and the elongated electrode segments of the first and second electrode layers. As a result, there may be non-uniformity in operating parameters of the piezoelectric device during bulk manufacturing and may lead to low device yields.

Various embodiments of the present disclosure provide a piezoelectric device including a piezoelectric structure disposed between patterned conductive structures, as well as an associated method for forming the piezoelectric device. For example, the piezoelectric device includes a first conductive structure disposed on a lower surface of the piezoelectric structure and a second conductive structure disposed on an upper surface of the piezoelectric structure. The first and second conductive structures respectively comprise one or more movable elements that include one or more electrode plates and/or a plurality of elongated electrode segments spaced alternatingly with one another. In some instances, by virtue of the first and second conductive structures each including the one or more electrode plates and the plurality of elongated electrode segments, the piezoelectric device may have two or more operating modes (e.g., the piezoelectric device can operate in a d31 mode and a d33 mode). As a result, an operating range and/or a piezoelectric effect of the piezoelectric device is increased, thereby increasing an output efficiency and sensitivity of the piezoelectric device.

Further, in some embodiments, a method for forming the piezoelectric device includes forming the piezoelectric structure over a handle substrate. A first conductive structure is deposited on the piezoelectric structure and a first patterning process is performed to define the one or more electrode plates and the plurality of elongated electrode segments in the first conductive structure. A dielectric structure is deposited on the first conductive structure and a second patterning process is performed to define a cavity in the dielectric structure. Subsequently, the dielectric structure is bonded to a semiconductor substrate (e.g., a carrier substrate). Further, the second conductive structure is formed over the piezoelectric structure. By virtue of the cavity being formed before bonding the dielectric structure to the semiconductor substrate, misalignment between the cavity and patterned features of the first and second conductive structures is reduced. As a result, fabrication complexity is reduced and a piezoelectric effect of the piezoelectric device is increased. Accordingly, a sensitivity and overall performance of the piezoelectric device are increased.

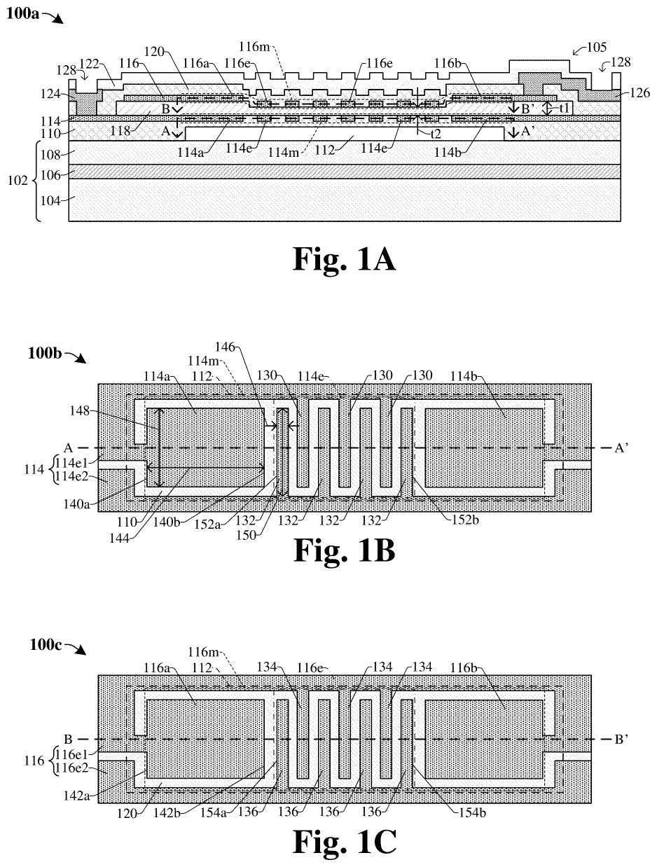

FIGS. 1A-1C illustrate various views 100a-c of some embodiments of a semiconductor structure including a piezoelectric device comprising a piezoelectric structure disposed between patterned conductive structures. FIG. 1A illustrates a cross-sectional view 100a of some embodiments of the semiconductor structure. FIG. 1B illustrates a top view 100b of some embodiments of the semiconductor structure taken along the line A-A′ of FIG. 1A. FIG. 1C illustrates a top view 100c of some embodiments of the semiconductor structure taken along the line B-B′ of FIG. 1A.

As illustrated in the cross-sectional view 100a, the semiconductor structure comprises a piezoelectric device 105 disposed on a semiconductor substrate 102. The semiconductor substrate 102 may, for example, be or comprise a bulk semiconductor substrate such as a bulk silicon substrate, a silicon-on-insulator (SOI) substrate, some other similar substrate, or any combination of the foregoing. In some embodiments, the semiconductor substrate 102 comprises a first substrate 104, an insulator layer 106, and a second substrate 108. Further, the semiconductor substrate 102 may be configured as and/or referred to as a carrier substrate. The piezoelectric device 105 comprises a piezoelectric structure 118 disposed between a first conductive structure 114 and a second conductive structure 116. The first conductive structure 114 is vertically spaced apart from the second conductive structure 116 by the piezoelectric structure 118.

A first dielectric structure 110 is disposed between the first conductive structure 114 and the semiconductor substrate 102. In some embodiments, the first dielectric structure 110 comprises opposing sidewalls defining a cavity 112, where the cavity directly underlies the first and second conductive structures 114, 116 A second dielectric structure 120 overlies the first and second conductive structures 114, 116. A first contact electrode 124 is disposed on a first side of the piezoelectric device 105. The first contact electrode 124 extends through the second dielectric structure 120 and directly contacts the first conductive structure 114, where the first contact electrode 124 is directly electrically coupled to the first conductive structure 114. A second contact electrode 126 is disposed on a second side of the piezoelectric device 105 opposite the first side of the piezoelectric device 105. The second contact electrode 126 extends through the second dielectric structure 120 and directly contacts the second conductive structure 116, where the second contact electrode 126 is directly electrically coupled to the second conductive structure 116. A passivation layer 122 directly overlies the second dielectric structure 120. The passivation layer 122 comprises opposing sidewalls that define contact openings 128 over the first and second contact electrodes 124, 126.

In various embodiments, the first conductive structure 114 comprises one or more first movable elements 114m disposed along a lower surface of the piezoelectric structure 118 and the second conductive structure 116 comprises one or more second movable elements 116m disposed along an upper surface of the piezoelectric structure 118. The one or more first movable elements 114m may, for example, comprise a first electrode plate 114a, a second electrode plate 114b, and a plurality of elongated electrode segments 114e disposed laterally between the first and second electrode plates 114a, 114b of the first conductive structure 114. The one or more second movable elements 116m may, for example, comprise a first electrode plate 116a, a second electrode plate 116b, and a plurality of elongated electrode segments 116e disposed laterally between the first and second electrode plates 116a, 116b of the second conductive structure 116.

During operation of the piezoelectric device 105, one or more bias voltage(s) may be applied to the first conductive structure 114 and the second conductive structure 116. An electric field generated by the one or more bias voltage(s) can cause the piezoelectric structure 118 to bend and/or move from an initial position. This bending and/or movement of the piezoelectric structure 118 may be used to control various kinds of systems (e.g., audio systems, mechanical systems, etc.) or generate sound waves. In other embodiments, during operation of the piezoelectric device 105, force from external stimuli (e.g., sound waves) may cause the piezoelectric structure 118 to bend and/or move from an initial position. The bending and/or movement of the piezoelectric structure 118 generates charges that form a potential difference between the first conductive structure 114 and the second conductive structure 116. The potential difference can be used to determine a degree of the bending and/or movement and a characteristic of the external stimuli. Further, by virtue of the one or more first movable elements 114m and the one or more second movable elements 116m being disposed on surfaces of the piezoelectric structure 118, the one or more first and second movable elements 114m, 116m are configured to move when the piezoelectric structure 118 bends and/or moves in response to generated electric fields and/or external stimuli. In yet further embodiments, a segment of the piezoelectric structure 118 between the one or more first and second movable elements 114m, 116m may be referred to as a movable membrane, a cantilever beam, or the like. In some embodiments, the piezoelectric device 105 is configured as a piezoelectric ultrasonic transducer (PMUT), a microelectromechanical systems (MEMS) transducer, or some other suitable device.

In various embodiments, the piezoelectric structure 118 comprises a first thickness t1 disposed in a peripheral region of the piezoelectric device 105 and a second thickness t2 disposed in a middle region of the piezoelectric device 105. The first thickness t1 is greater than the second thickness t2. For example, the second thickness t2 may be within a range of about 30% to about 80% of the first thickness t1. As a result of the second thickness t2 being less than the first thickness t1, the piezoelectric structure 118 is less rigid in the middle region of the piezoelectric device 105. This, in part, increases an ability for the piezoelectric structure 118 to bend, thereby increasing a sensitivity and overall performance of the piezoelectric device 105.

In some embodiments, during fabrication of the piezoelectric device 105, the one or more first movable elements 114m of the first conductive structure 114 is/are formed by a first patterning process. The first dielectric structure 110 is then deposited on the first conductive structure 114. Further, a second patterning process is performed on the first dielectric structure 110 to form the cavity 112. Subsequently, the first dielectric structure 110 is bonded to the semiconductor substrate 102. By virtue of the cavity 112 being formed before bonding the first dielectric structure 110 to the semiconductor substrate 102, misalignment between the cavity 112 and the one or more first movable elements 114m and the one or more second movable elements 116m is reduced. As a result, fabrication complexity is reduced and a piezoelectric effect of the piezoelectric device 105 is increased. Accordingly, a sensitivity and overall performance of the piezoelectric device 105 are increased.

In yet further embodiments, by virtue of the one or more first movable elements 114m comprising the first and second electrode plates 114a, 114b and the one or more second movable elements 116m comprising the first and second electrode plates 116a, 116b, the piezoelectric device 105 may operate in a first operating mode (e.g., in a d31 mode). For example, one or more bias voltages may be applied across the first and second conductive structures 114, 116 thereby generating first electric field(s) between the first and second plates of the first and second conductive structures 114, 116. The first electric field(s) extend in a first direction orthogonal to the upper surface of the piezoelectric structure 118. As a result, a thickness of the piezoelectric structure 118 in regions between the first and second plates of the first and second conductive structures 114, 116 changes (e.g., the thickness increases). Further, by virtue of the one or more first movable elements 114m comprising the elongated electrode segments 114e and the one or more second movable elements 116m comprising the elongated electrode segments 116e, the piezoelectric device 105 may further operate in a second operating mode (e.g., in a d33 mode). For example, one or more bias voltages may be applied across the first and second conductive structures 114, 116 thereby generating second electric field(s) between the elongated electrode segments of the first and second conductive structures 114, 116. The second electric field(s) extend in a second direction parallel to the upper surface of the piezoelectric structure 118. As a result, a thickness of the piezoelectric structure 118 in regions between the elongated electrode segments of the first and second conductive structures 114, 116 changes (e.g., the thickness decreases). Accordingly, in some embodiments, the piezoelectric device 105 has two or more operating modes (e.g., both the first operation mode and the second operating mode). As a result, an operating range and/or a piezoelectric effect of the piezoelectric device 105 is increased, thereby increasing an output efficiency and sensitivity of the piezoelectric device 105.

With reference to the top views 100b and 100c of FIGS. 1B and 1C, in some embodiments, the first conductive structure 114 comprises a first electrode structure 114e1 and a second electrode structure 114e2. In some instances, a discontinuity is present in the first conductive structure 114 in order to electrically isolate the first electrode structure 114e1 from the second electrode structure 114e2. The first dielectric structure 110 is disposed in the discontinuity of the first conductive structure 114 to facilitate electrical isolation between the first and second electrode structures 114e1, 114e2. The first electrode structure 114e1 comprises the first and second electrode plates 114a, 114b of the first conductive structure 114 and a first subset 130 of the elongated electrode segments 114e of the first conductive structure 114. The second electrode structure 114e2 comprises a second subset 132 of the elongated electrode segments 114e of the first conductive structure 114.

Further, in some embodiments, the second conductive structure 116 comprises a first electrode structure 116e1 and a second electrode structure 116e2. In some instances, a discontinuity is present in the second conductive structure 116 in order to electrically isolate the first electrode structure 116e1 from the second electrode structure 116e2. The second dielectric structure 120 is disposed in the discontinuity of the second conductive structure in order to facilitate electrical isolation between the first and second electrode structures 116e1, 116e2. The first electrode structure 116e1 comprises the first and second electrode plates 116a, 116b of the second conductive structure 116 and a first subset 134 of the elongated electrode segments 116e of the second conductive structure 116. Further, the second electrode structure 116e2 comprises a second subset 136 of the elongated electrode segments 116e of the second conductive structure 116.

In some embodiments, during operation of the piezoelectric device (105 of FIG. 1A), a first voltage is applied across the first and second electrode structures 114e1, 114e2 of the first conductive structure 114 and a second voltage is applied across the first and second electrode structures 116e1, 116e2 of the second conductive structure 116. By virtue of both the first conductive structure 114 and the second conductive structure 116 comprising one or more movable elements on opposing surfaces of the piezoelectric structure (118 of FIG. 1A), bending and/or movement of the piezoelectric structure (118 of FIG. 1A) may be increased. As a result, a sensitivity and overall performance of the piezoelectric device (105 of FIG. 1A) are increased. Further, by virtue of the first and second conductive structures 114, 116 respectively comprising one or more electrode plates and the plurality of elongated electrode segments, the piezoelectric device (105 of FIG. 1A) has multiple operating modes (e.g., may operate in a d31 mode and/or a d33 mode). This increases an output efficiency and sensitivity of the piezoelectric device (105 of FIG. 1A). Further, as illustrated in FIGS. 1B and 1C, a layout of the first conductive structure 114 is symmetrical and/or the same as a layout of the second conductive structure 116. This increases a uniformity of electric fields generated by biasing the first and second conductive structures 114, 116 with one or more bias voltage(s) and/or increases an ability to accurately measure a potential difference between the first and second conductive structures 114, 116. In various embodiments, the first and second voltages applied across the first and second conductive structures 116 are selected such that an electric field between the first and second conductive structures 114, 116 is, for example, about 1,000 kV/cm or some other suitable value.

The first and second conductive structures 114, 116 may, for example, be or comprise platinum, gold, zinc, copper, ruthenium, rhodium, palladium, osmium, iridium, silver, tungsten, tin, some other conductive material, or any combination of the foregoing. In various embodiments, the first and second conductive structures 114, 116 may comprise a conductive material with a temperature coefficient of resistance within a range of about 0.003 to about 0.006 or some other suitable value. The piezoelectric structure 118 may, for example, be or comprise lead zirconate titanate (PZT), aluminum nitride, zinc oxide, some other piezoelectric material, or any combination of the foregoing. The first and second dielectric structures 110, 120 may, for example, be or comprise silicon oxide, aluminum oxide, tantalum oxide, hafnium oxide, silicon nitride, yttrium oxide, zirconium oxide, titanium oxide, lanthanum oxide, some other dielectric material, or any combination of the foregoing. In various embodiments, the first and second dielectric structures 110, 120 may each comprise a stack of one or more dielectric layers, each of which may be or comprise silicon oxide, aluminum oxide, tantalum oxide, hafnium oxide, silicon nitride, yttrium oxide, zirconium oxide, titanium oxide, lanthanum oxide, or some other dielectric material. The first and second contact electrodes 124, 126 may, for example, be or comprise platinum, gold, zinc, copper, aluminum, titanium, titanium nitride, tungsten titanium, ruthenium, some other conductive material, or any combination of the foregoing. In various embodiments, the first and second contact electrodes 124, 126 may comprise conductive material with a temperature coefficient of resistance within a range of about 0.003 to about 0.006 or some other suitable value. The passivation layer 122 may, for example, be or comprise silicon oxide, aluminum oxide, tantalum oxide, hafnium oxide, silicon nitride, yttrium oxide, zirconium oxide, titanium oxide, lanthanum oxide, some other dielectric material, or any combination of the foregoing.

In various embodiments, opposing sidewalls 140a, 140b of the first electrode plate 114a of the first conductive structure 114 are aligned with opposing sidewalls 142a, 142b of the first electrode plate 116a of the second conductive structure 116. In some embodiments, a width 144 of the first electrode plate 114a is greater than a width 146 of an individual elongated electrode segment in the plurality of elongated electrode segments 114e of the first conductive structure 114. In further embodiments, a length 148 of the first electrode plate 114a is less than a length 150 of an individual elongated electrode segment in the plurality of elongated electrode segments 114e of the first conductive structure 114. In yet further embodiments, opposing sidewalls 152a, 152b of the plurality of elongated electrode segments 114e of the first conductive structure 114 are aligned with opposing sidewalls 154a, 154b of the plurality of elongated electrode segments 116e of the second conductive structure 116.

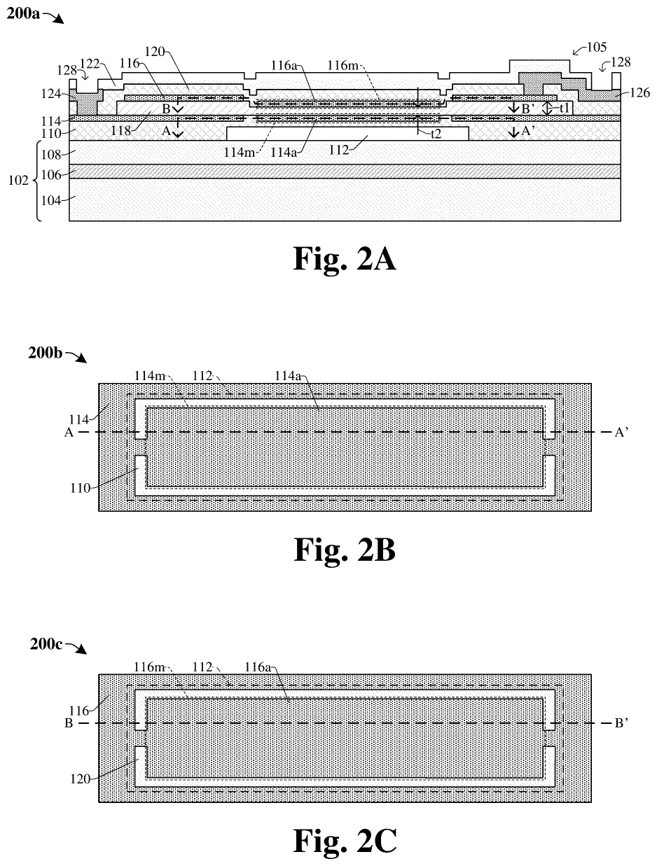

FIGS. 2A-2C illustrate various views 200a-c of some other embodiments of the semiconductor structure of FIGS. 1A-1C, in which the one or more first movable elements 114m comprises a first electrode plate 114a and the one or more second movable elements 116m comprises a first electrode plate 116a. In such embodiments, the second electrode plates (114b, 116b of FIG. 1A) and the plurality of elongated electrode segments (114e, 116e of FIG. 1A) of the first and second conductive structures 114, 116 are omitted. FIG. 2A illustrates a cross-sectional view 200a of some embodiments of the semiconductor structure. FIG. 2B illustrates a top view 200b of some embodiments of the semiconductor structure taken along the line A-A′ of FIG. 2A. FIG. 2C illustrates a top view 200c of some embodiments of the semiconductor structure taken along the line B-B′ of FIG. 2A.

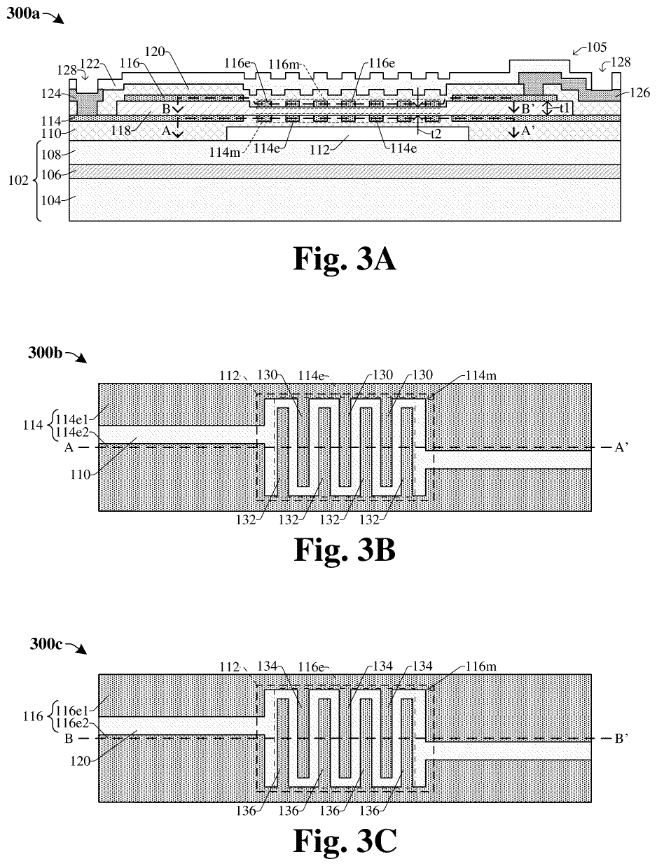

FIGS. 3A-3C illustrate various views 300a-c of some other embodiments of the semiconductor structure of FIGS. 1A-1C, in which the one or more first movable elements 114m comprises the plurality of elongated electrode segments 114e and the one or more second movable elements 116m comprises the plurality of elongated electrode segments 116e. In such embodiments, the plate electrodes (114a-b, 116a-b of FIG. 1A) of the first and second conductive structures 114, 116 are omitted. FIG. 3A illustrates a cross-sectional view 300a of some embodiments of the semiconductor structure. FIG. 3B illustrates a top view 300b of some embodiments of the semiconductor structure taken along the line A-A′ of FIG. 3A. FIG. 3C illustrates a top view 300c of some embodiments of the semiconductor structure taken along the line B-B′ of FIG. 3A.

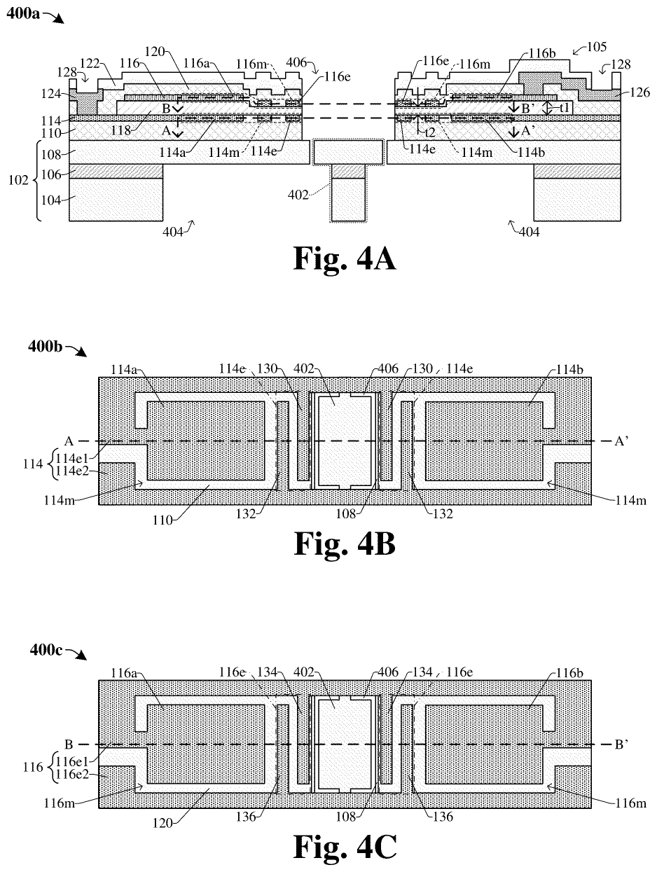

FIGS. 4A-4C illustrate various views 400a-c of some additional embodiments of a semiconductor structure including a piezoelectric device comprising a piezoelectric structure disposed between patterned conductive structures. FIG. 4A illustrates a cross-sectional view 400a of some embodiments of the semiconductor structure. FIG. 4B illustrates a top view 400b of some embodiments of the semiconductor structure taken along the line A-A′ of FIG. 4A. FIG. 4C illustrates a top view 400c of some embodiments of the semiconductor structure taken along the line B-B′ of FIG. 4A.

The semiconductor structure of FIGS. 4A-4C includes similar features as the semiconductor structure in FIGS. 1A-1C, with the addition of an opening 406 extending through a middle region of the piezoelectric device 105 and a lower movable element 402 suspended under the opening 406. In various embodiments, sidewalls of the first and second dielectric structures 110, 120, sidewalls of the piezoelectric structure 118, sidewalls of the passivation layer 122, and sidewalls of the first and second conductive structures 114, 116 define the opening 406. Further, the semiconductor substrate 102 comprises the lower movable element 402 suspended under the opening 406. In various embodiments, the lower movable element 402 may be a diaphragm structure configured to produce sound waves in conjunction with the piezoelectric structure 118 and the first and second conductive structures 114, 116. In yet further embodiments, the lower movable element 402 may be a proof mass configured to amplify bending of the piezoelectric structure 118. Further, the semiconductor substrate 102 comprises sidewalls defining lower openings 404 under the first dielectric structure 110. The lower openings 404 may be configured as a cavity and may reduce rigidity of the lower movable element 402 and/or the piezoelectric structure 118, thereby increasing a sensitivity and overall performance of the piezoelectric device 105.

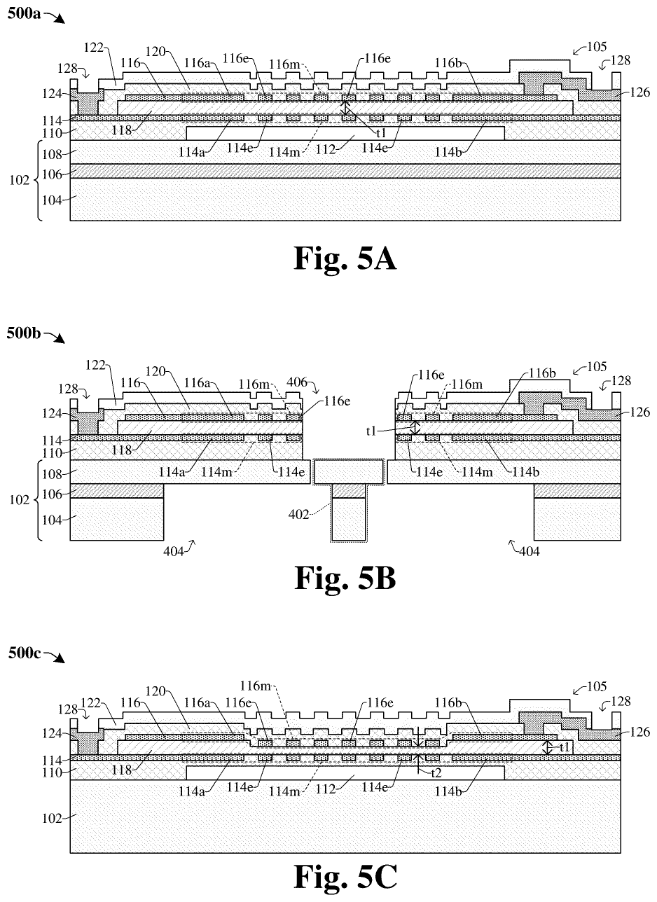

FIG. 5A illustrates a cross-sectional view 500a of some other embodiments of the semiconductor structure of FIG. 1A, in which the piezoelectric structure 118 has the first thickness t1 across a length of the piezoelectric structure 118.

FIG. 5B illustrates a cross-sectional view 500b of some other embodiments of the semiconductor structure of FIG. 4A, in which the piezoelectric structure 118 has the first thickness t1 across a length of the piezoelectric structure 118.

FIG. 5C illustrates a cross-sectional view 500c of some other embodiments of the semiconductor structure of FIG. 1A, in which the semiconductor substrate 102 comprises a single semiconductor substrate body. For example, the semiconductor substrate 102 may be or comprise a bulk substrate, monocrystalline silicon, some other suitable substrate material, or the like.

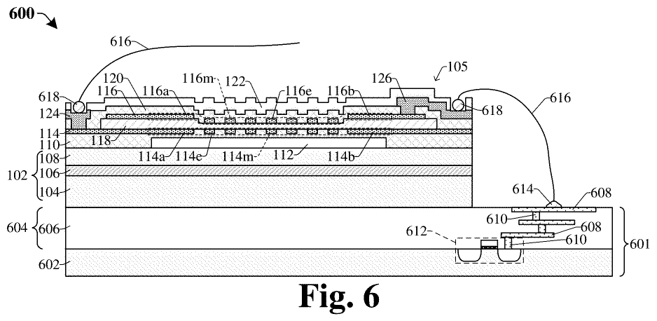

FIG. 6 illustrates a cross-sectional view 600 of some embodiments of a piezoelectric device coupled to a transistor in an integrated circuit (IC) chip.

As illustrated in the cross-sectional view 600, an IC chip 601 underlies the semiconductor substrate 102. The IC chip 601 includes an interconnect structure 604 disposed on a substrate 602. A transistor 612 is disposed within and/or on the substrate 602. The transistor 612 is electrically coupled to the piezoelectric device 105. In some instances, the transistor 612 is a metal oxide semiconductor field-effect transistor (MOSFET), a fin field-effect transistor (FinFET), or the like. Further, the transistor 612 comprises a gate dielectric (not labeled) disposed on the substrate 602, a gate electrode (not labeled) over the gate dielectric, and a pair of source/drain regions (not labeled) disposed on opposing sides of the gate electrode. The interconnect structure 604 comprises a plurality of conductive wires 608 and a plurality of conductive vias 610 disposed within a dielectric structure 606. A connector pad 614 overlies a topmost conductive wire in the plurality of conductive wires 608 and provides a wire bonding location for a metal wire 616. Further, solder balls 618 overlie the first and second contact electrodes 124, 126. The solder balls 618 provide contact points for the metal wires 616. The piezoelectric device 105 is directly electrically coupled to the interconnect structure 604 by way of at least the solder balls 618, the metal wires 616, and/or the connector pad 614.

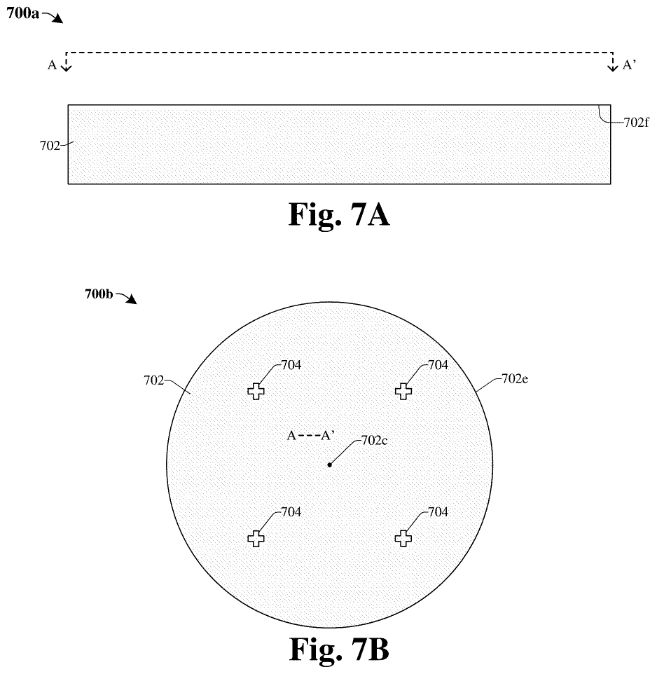

FIGS. 7A-23 illustrate various views 700a-2300 of some embodiments of a first method of forming a piezoelectric device comprising a piezoelectric structure disposed between patterned conductive structures. Although the various views 700a-2300 shown in FIGS. 7A-23 are described with reference to a first method, it will be appreciated that the structures shown in FIGS. 7A-23 are not limited to the first method but rather may stand alone separate of the first method. Furthermore, although FIGS. 7A-23 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

As shown in cross-sectional view 700a and top view 700b respectively of FIGS. 7A and 7B, a handle substrate 702 is provided. The handle substrate 702 may, for example, be or comprise a bulk substrate, monocrystalline silicon, some other suitable substrate material, or the like. In some embodiments, a plurality of alignment marks 704 are disposed on the handle substrate 702. The alignment marks 704 may comprise a cross shape or some other suitable shape. Further, the alignment marks 704 may comprise Moire patterns. Further, the alignment marks 704 may be defined by recesses (e.g., trenches) within a surface of the handle substrate 702 (e.g., having a depth of about 1 micrometer or more). In some embodiments, a process for forming the plurality of alignment marks 704 includes: forming a patterned masking layer (not shown) over a front-side surface 702f of the handle substrate 702; performing an etching process (e.g., a dry etch process, a wet etch process, or the like) on the handle substrate 702 to form one or more trenches extending into the front-side surface 702f (e.g., having a depth of about 1 micrometer or more), where the alignment marks 704 are defined by the one or more trenches; and performing a removal process to remove the patterned masking layer.

FIG. 7B illustrates the top view 700b corresponding to some embodiments of the cross-sectional view 700a taken along the line A-A′ of FIG. 7A. As illustrated in FIG. 7B, the alignment marks 704 each have a cross shape. However, it will be appreciated that the alignment marks 704 may have other shapes and/or sizes and/or may be located in other regions of the handle substrate 702. For example, the alignment marks 704 may be disposed near a circumferential edge 702e of the handle substrate 702 (not shown). In some embodiments, the alignment marks 704 are equidistant from a center 702c of the handle substrate 702.

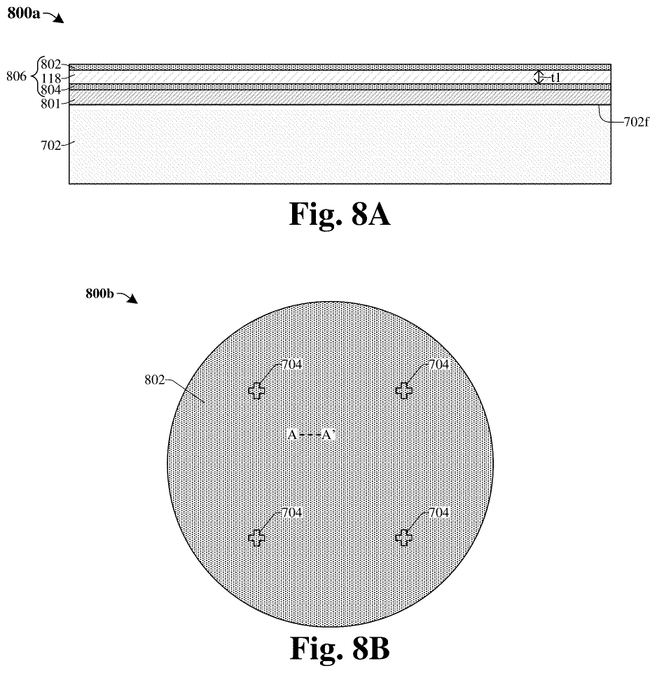

As shown in cross-sectional view 800a and top view 800b respectively of FIGS. 8A and 8B, an insulator structure 801 and a stack of piezoelectric layers 806 are formed over the handle substrate 702. The insulator structure 801 may be formed on the handle substrate 702 by, for example, an oxidation process, chemical vapor deposition (CVD), physical vapor deposition (PVD), atomic layer deposition (ALD), or some other suitable growth or deposition process. The stack of piezoelectric layers 806 comprises a piezoelectric structure 118 disposed between a first conductive layer 802 and a second conductive layer 804. The second conductive layer 804 may be formed on the insulator structure 801 by, for example, an electron beam gun (E-Gun) process, sputtering, electroplating, screen printing, PVD, or some other suitable growth or deposition process. The piezoelectric structure 118 may be formed on the second conductive layer 804 by, for example, a sol-gel process, PVD, CVD, ALD, or some other suitable growth or deposition process. Further, the first conductive layer 802 may be formed on the piezoelectric structure 118 by, for example, an E-Gun process, sputtering, electroplating, screen printing, PVD, or some other suitable growth or deposition process.

The insulator structure 801 may, for example, be or comprise silicon oxide, silicon nitride, aluminum oxide, tantalum oxide, hafnium oxide, some other suitable dielectric material, or any combination of the foregoing. In some embodiments, the insulator structure 801 has a thickness within a range of about 10 nanometers (nm) to about 10,000 nm or some other suitable value. The first and second conductive layers 802, 804 may, for example, be or comprise platinum, gold, zinc, copper, ruthenium, rhodium, palladium, osmium, iridium, silver, tungsten, tin, some other conductive material, or any combination of the foregoing. Further, the first and second conductive layers 802, 804 may each have a thickness within a range of about 20 nm to about 500 nm or some other suitable value. The piezoelectric structure 118 may, for example, be or comprise lead zirconate titanate (PZT), aluminum nitride, zinc oxide, some other piezoelectric material, or any combination of the foregoing. The piezoelectric structure 118 is formed to a first thickness t1 that is within a range of about 100 nm to about 2,000 nm or some other suitable value.

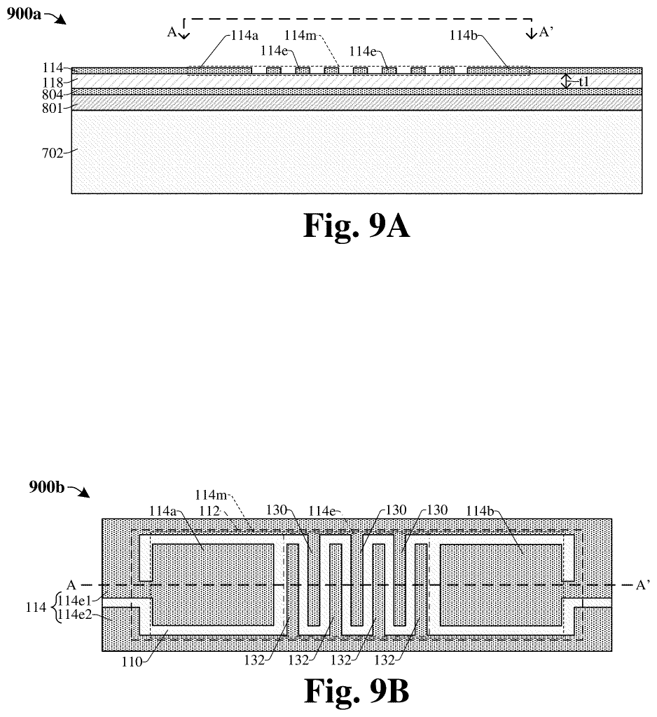

FIG. 8B illustrates the top view 800b corresponding to some embodiments of the cross-sectional view 800a taken along the line A-A′ of FIG. 8A. As illustrated in FIG. 8B, by virtue of a topography of the alignment marks 704 in the handle substrate (702 of FIG. 8A), the alignment marks 704 are present in the stack of piezoelectric layers (806 of FIG. 8A) and/or the insulator structure (801 of FIG. 8A). In some embodiments, this is because the alignment marks 704 are defined by recesses (e.g., trenches) within the front-side surface (702f of FIG. 8A) of the handle substrate (702 of FIG. 8A) and the stack of piezoelectric layers (806 of FIG. 8A) and/or the insulator structure (801 of FIG. 8A) are formed by one or more conformal deposition or growth processes that conform to shapes of the alignment marks 704. This causes the alignment marks 704 to be detectable and/or present in individual layers of the stack of piezoelectric layers (806 of FIG. 8A) and/or the insulator structure (801 of FIG. 8A). Accordingly, subsequent processing steps may be aligned according to the plurality of alignment marks 704. For example, the first patterning process of FIGS. 9A and 9B may include aligning the patterned masking layer (not shown) according to the plurality of alignment marks 704. As a result, patterned features of the first conductive structure (114 of FIGS. 9A and 9B) are aligned by virtue of at least the plurality of alignment marks 704.

As shown in cross-sectional view 900a of FIG. 9A and top view 900b of FIG. 9B, a first patterning process is performed on the first conductive layer (802 of FIG. 8) to form a first conductive structure 114 comprising one or more first movable elements 114m on the piezoelectric structure 118. In various embodiments, the first patterning process forms the one or more first movable elements 114m in the first conductive structure 114, where the one or more first movable elements 114m comprise a first electrode plate 114a, a second electrode plate 114b, and a plurality of elongated electrode segments 114e disposed laterally between the first and second electrode plates 114a, 114b.

In some embodiments, the first patterning process comprises: forming a patterned masking layer (not shown) over the first conductive layer (802 of FIG. 8); performing an etching process according to the patterned masking layer, thereby defining the first conductive structure 114 and the one or more first movable elements 114m; and performing a removal process to remove the patterned masking layer. Further, the first patterning process may be performed within a processing chamber at a temperature within a range of about 20 degrees Celsius to about 100 degrees Celsius or some other suitable value. The etching process, may for example, be or comprise an ion beam etching process, a reactive-ion etching process, a wet etch process, some other suitable etching process, or any combination of the foregoing. In yet further embodiments, the patterned masking layer (not shown) and/or the etching process may be aligned by virtue of at least the plurality of alignment marks (704 of FIG. 8B). As a result, the one or more first movable elements 114m of the first conductive structure 114 are aligned according to the plurality of alignment marks (704 of FIG. 8B). In some instances, aligning the patterned masking layer (not shown) and/or the etching process by virtue of at least the plurality of alignment marks (704 of FIG. 8B) includes utilizing a light sensor (e.g., an infrared (IR) sensor) (not shown) to illuminate light (e.g., IR light) towards a top surface of the stack of piezoelectric layers (806 of FIG. 8A) to detect locations of the alignment marks (704 of FIG. 8B). In such embodiments, the light sensor and/or the illuminated light are used to align a photomask (not shown) that is used to perform the first patterning process (e.g., the photomask is used to form the patterning masking layer). In further embodiments, the first patterning process includes performing a lift off patterning process or some other suitable patterning process. Further, it will be appreciated that while FIGS. 9A and 9B illustrate the first patterning process forming the first conductive structure 114 as illustrated and/or described in FIGS. 1A and 1B, the first patterning process may be performed such that the first conductive structure 114 is configured as illustrated and/or described in FIG. 2A-2B or 3A-3B.

FIG. 9B illustrates the top view 900b corresponding to some embodiments of the cross-sectional view 900a taken along the line A-A′ of FIG. 9A. FIG. 9B illustrates a layout of the first conductive structure 114 after the first patterning process. In various embodiments, the first conductive structure comprises a first electrode structure 114e1 and a second electrode structure 114e2. In some instances, a discontinuity is present in the first conductive structure 114 in order to electrically isolate the first electrode structure 114e1 from the second electrode structure 114e2, where the first patterning process forms the discontinuity in the first conductive structure 114. The first electrode structure 114e1 comprises the first and second electrode plates 114a, 114b and a first subset 130 of the elongated electrode segments 114e. The second electrode structure 114e2 comprises a second subset 132 of the elongated electrode segments 114e.

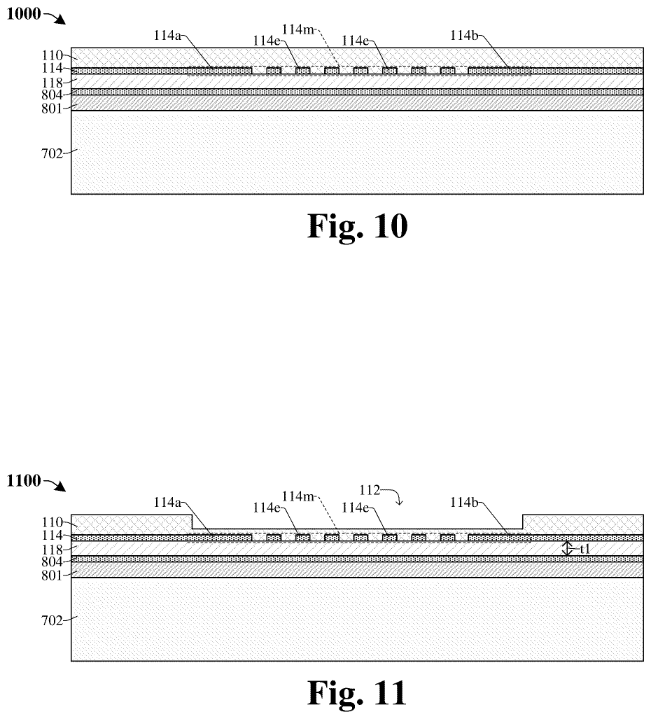

As shown in cross-sectional view 1000 of FIG. 10, a first dielectric structure 110 is formed over the first conductive structure 114 and the piezoelectric structure 118. The first dielectric structure 110 may be formed on the first conductive structure 114 by, for example, CVD, ALD, PVD, or some other suitable growth or deposition process. The first dielectric structure 110 may, for example, be or comprise silicon oxide, aluminum oxide, tantalum oxide, hafnium oxide, silicon nitride, yttrium oxide, zirconium oxide, titanium oxide, lanthanum oxide, some other dielectric material, or any combination of the foregoing. In some embodiments, the first dielectric structure 110 has a thickness within a range of about 100 nm to about 10,000 nm or some other suitable value. In yet further embodiments, the first dielectric structure 110 may comprise a multi-layer dielectric stack (not shown) comprising two or more dielectric layers having different materials from one another. In various embodiments, the first dielectric structure 110 is formed (e.g., by a conformal deposition process) such that the alignment marks (704 of FIG. 8B) are detectable and/or present in the first dielectric structure 110.

As shown in cross-sectional view 1100 of FIG. 11, a second patterning process is performed on the first dielectric structure 110 to form a cavity 112 over the first conductive structure 114. In some embodiments, the second patterning process comprises: forming a patterned masking layer (not shown) over the first dielectric structure 110; performing an etching process according to the patterned masking layer, thereby defining the cavity 112 within the first dielectric structure 110; and performing a removal process to remove the patterned masking layer. The second patterning process may be performed within a processing chamber at a temperature within a range of about 20 degrees Celsius to about 100 degrees Celsius or some other suitable value. The etching process, may for example, be or comprise an ion beam etching process, a reactive-ion etching process, a wet etch process, some other suitable etching process, or any combination of the foregoing. In yet further embodiments, in which the first dielectric structure 110 comprises two or more dielectric layers (not shown), the two or more dielectric layers have different etching selectively during the second patterning process such that a depth of the cavity 112 may be more accurately defined. In further embodiments, the second patterning process may be aligned by virtue of at least the plurality of alignment marks (704 of FIG. 8B), as illustrated and/or described in FIGS. 9A and 9B above. As a result, the cavity 112 is aligned with the one or more first movable elements 114m of the first conductive structure 114.

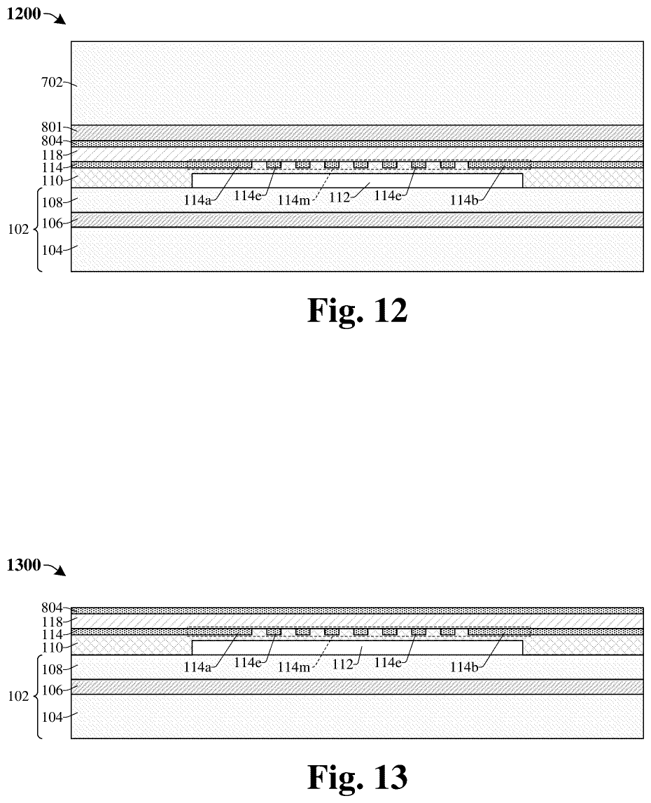

As shown in cross-sectional view 1200 of FIG. 12, a bonding process is performed to bond the first dielectric structure 110 to a semiconductor substrate 102. In various embodiments, the bonding process includes performing a fusion bonding process or some other suitable bonding process. In further embodiments, the bonding process includes exposing the first dielectric structure 110 and the semiconductor substrate 102 to a temperature within a range of about 20 degrees Celsius to about 100 degrees Celsius or some other suitable value. The bonding process may seal the cavity 112 to a first gas pressure. The semiconductor substrate 102 may, for example, be or comprise a bulk semiconductor substrate such as a bulk silicon substrate, a silicon-on-insulator (SOI) substrate, some other similar substrate, or any combination of the foregoing. In some embodiments, the semiconductor substrate 102 comprises a first substrate 104, an insulator layer 106, and a second substrate 108.

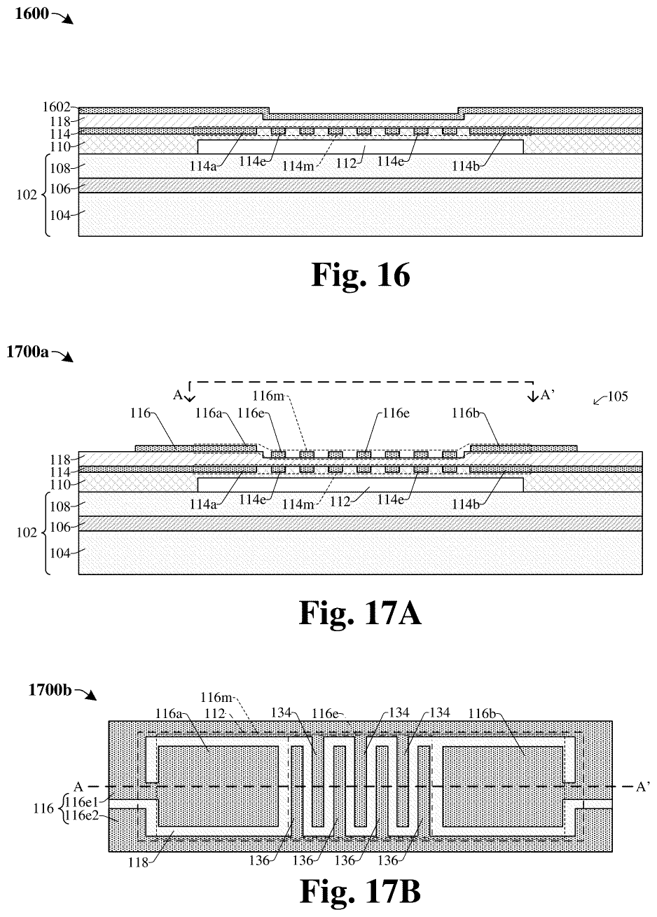

In some embodiments, patterned structures are not disposed on the semiconductor substrate 102 such that the bonding process is performed without an optical alignment process. As a result, fabrication costs and complexity are reduced. Further, misalignment between the cavity 112, the one or more first movable elements 114m, and/or other patterned features (e.g., the one or more second movable elements 116m of FIGS. 17A and 17B) is reduced.

As shown in cross-sectional view 1300 of FIG. 13, a removal process is performed to remove the handle substrate (702 of FIG. 12) and the insulator structure (801 of FIG. 12). The removal process may, for example, include: removing the handle substrate (702 of FIG. 12) by a chemical mechanical planarization (CMP) process, a mechanical grinding process, or the like, and removing the insulator structure (801 of FIG. 12) by an ion beam etching process, a reactive-ion etching process, a wet etch process, or the like. The removal process may be performed at a temperature within a range of about 20 degrees Celsius to about 100 degrees Celsius or some other suitable value. By virtue of a topography of the alignment marks (704 of FIG. 8B), the alignment marks (704 of FIG. 8B) are detectable and/or present in the first dielectric structure 110, the first conductive structure 114, the piezoelectric structure 118, and/or the second conductive layer 804 after removing the handle substrate (702 of FIG. 12).

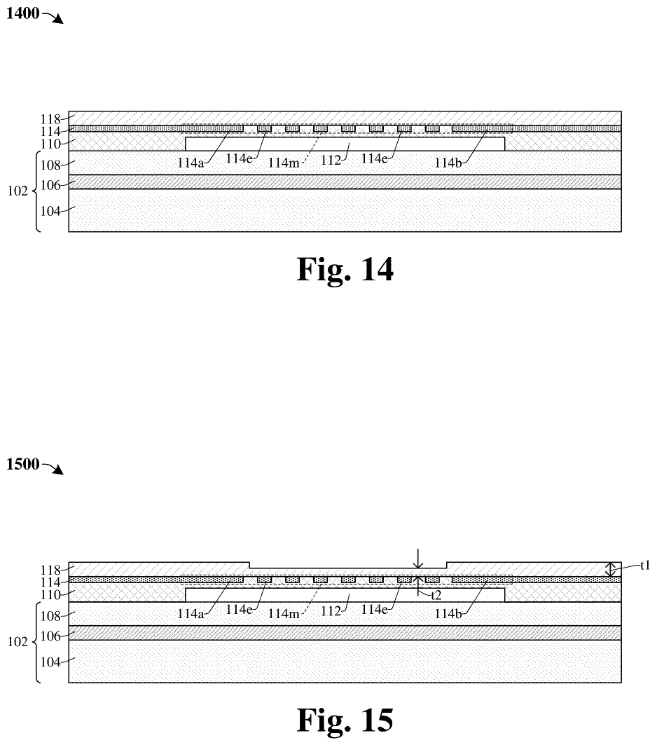

As shown in cross-sectional view 1400 of FIG. 14, an etching process is performed to remove the second conductive layer (804 of FIG. 13) and expose an upper surface of the piezoelectric structure 118. In various embodiments, the etching process includes performing an ion beam etching process, a reactive-ion etching process, a wet etch process, or the like. The etching process may be performed at a temperature within a range of about 20 degrees Celsius to about 100 degrees Celsius or some other suitable value.

As shown in cross-sectional view 1500 of FIG. 15, a patterning process is performed on the piezoelectric structure 118 such that the piezoelectric structure 118 has a second thickness t2 within a middle region of the piezoelectric structure 118. In some embodiments, the second thickness t2 is less than the first thickness t1. For example, the second thickness t2 may be within a range of about 30% to about 80% of the first thickness t1. In some embodiments, the patterning process comprises: forming a patterned masking layer (not shown) over the piezoelectric structure 118; performing an etching process according to the patterned masking layer, thereby defining the second thickness t2 within the middle region of the piezoelectric structure 118; and performing a removal process to remove the patterned masking layer. The patterning process may be performed within a processing chamber at a temperature within a range of about 20 degrees Celsius to about 100 degrees Celsius or some other suitable value. The etching process, may for example, be or comprise an ion beam etching process, a reactive-ion etching process, a wet etch process, some other suitable etching process, or any combination of the foregoing. In some embodiments, the patterning process may be aligned by virtue of at least the plurality of alignment marks (704 of FIG. 8B), as illustrated and/or described in FIGS. 9A and 9B above. As a result, a location of the second thickness t2 is aligned with the one or more first movable elements 114m and/or the cavity 112.

As shown in cross-sectional view 1600 of FIG. 16, a conductive layer 1602 is formed on the piezoelectric structure 118. The conductive layer 1602 may be formed on the piezoelectric structure 118 by, for example, an E-Gun process, sputtering, electroplating, screen printing, PVD, or some other suitable growth or deposition process. The conductive layer 1602 may, for example, be or comprise platinum, gold, zinc, copper, ruthenium, rhodium, palladium, osmium, iridium, silver, tungsten, tin, some other conductive material, or any combination of the foregoing. The conductive layer 1602 may have a thickness within a range of about 20 nm to about 500 nm or some other suitable value.

As shown in cross-sectional view 1700a of FIG. 17A and top view 1700b of FIG. 17B, a patterning process is performed on the conductive layer (1602 of FIG. 16), thereby forming a second conductive structure 116 comprising one or more second movable elements 116m along the upper surface of the piezoelectric structure 118 and a piezoelectric device 105. In some embodiments, the one or more second movable elements 116m comprise a first electrode plate 116a, a second electrode plate 116b, and a plurality of elongated electrode segments 116e disposed laterally between the first and second electrode plates 116a, 116b.

In some embodiments, the patterning process comprises: forming a patterned masking layer (not shown) over the conductive layer (1602 of FIG. 16); performing an etching process according to the patterned masking layer, thereby defining the second conductive structure 116 and the one or more second movable elements 116m; and performing a removal process to remove the patterned masking layer. Further, the patterning process may be performed within a processing chamber at a temperature within a range of about 20 degrees Celsius to about 100 degrees Celsius or some other suitable value. The etching process, may for example, be or comprise an ion beam etching process, a reactive-ion etching process, a wet etch process, some other suitable etching process, or any combination of the foregoing. In yet further embodiments, the patterned masking layer (not shown) and/or the etching process may be aligned by virtue of at least the plurality of alignment marks (704 of FIG. 8B), such that the one or more second movable elements 116m of the second conductive structure 116 are aligned according to the plurality of alignment marks (704 of FIG. 8B). As a result, the one or more second movable elements 116m are aligned with the cavity 112 and/or the one or more first movable elements 114m. In further embodiments, the patterning process includes performing a lift off patterning process or some other suitable patterning process.

FIG. 17B illustrates the top view 1700b corresponding to some embodiments of the cross-sectional view 1700a taken along the line A-A′ of FIG. 17A. FIG. 17B illustrates a layout of the second conductive structure 116 after the patterning process. In various embodiments, the second conductive structure 116 comprises a first electrode structure 116e1 and a second electrode structure 116e2. In some instances, a discontinuity is present in the second conductive structure 116 in order to electrically isolate the first electrode structure 116e1 from the second electrode structure 116e2, where the patterning process forms the discontinuity in the second conductive structure 116. The first electrode structure 116e1 comprises the first and second electrode plates 116a, 116b and a first subset 134 of the elongated electrode segments 116e. The second electrode structure 116e2 comprises a second subset 136 of the elongated electrode segments 116e.

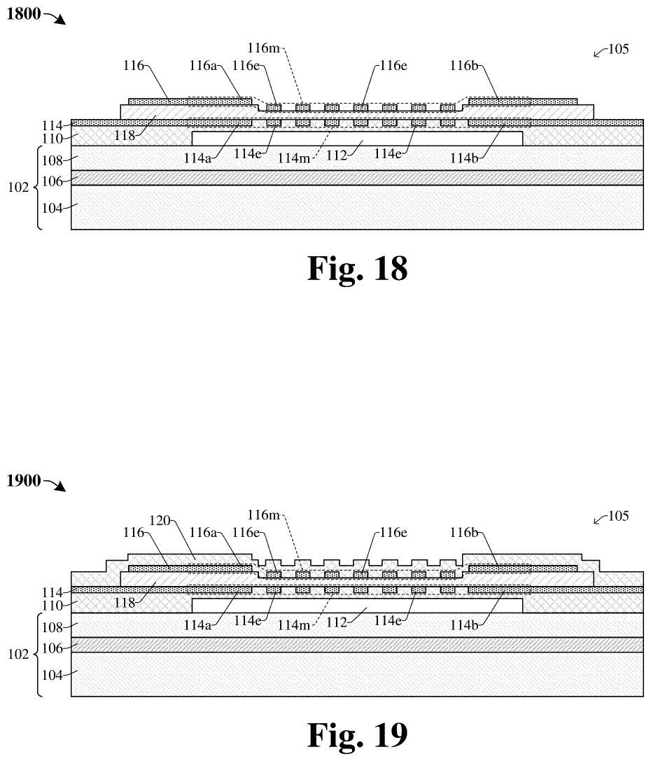

As shown in cross-sectional view 1800 of FIG. 18, a pattering process is performed on the piezoelectric structure 118 to remove the piezoelectric structure 118 from over outer regions of the first conductive structure 114. In some embodiments, the patterning process comprises: forming a patterned masking layer (not shown) over the piezoelectric structure 118; performing an etching process according to the patterned masking layer; and performing a removal process to remove the patterned masking layer. The patterning process may be performed within a processing chamber at a temperature within a range of about 20 degrees Celsius to about 100 degrees Celsius or some other suitable value. The etching process, may for example, be or comprise an ion beam etching process, a reactive-ion etching process, a wet etch process, some other suitable etching process, or any combination of the foregoing.

As shown in cross-sectional view 1900 of FIG. 19, a second dielectric structure 120 is formed over the piezoelectric device 105. The second dielectric structure 120 may be formed by, for example, CVD, ALD, PVD, or some other suitable growth or deposition process. The second dielectric structure 120 may, for example, be or comprise silicon oxide, aluminum oxide, tantalum oxide, hafnium oxide, silicon nitride, yttrium oxide, zirconium oxide, titanium oxide, lanthanum oxide, some other dielectric material, or any combination of the foregoing. In some embodiments, the second dielectric structure 120 has a thickness within a range of about 100 nm to about 10,000 nm or some other suitable value. In yet further embodiments, the second dielectric structure 120 may comprise a multi-layer dielectric stack (not shown) comprising two or more dielectric layers having different materials from one another.

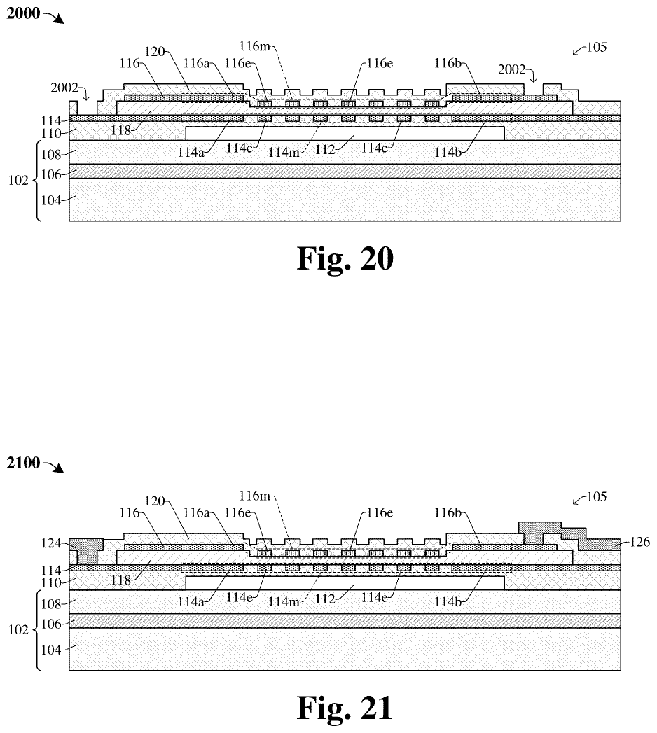

As shown in cross-sectional view 2000 of FIG. 20, a patterning process is performed on the second dielectric structure 120 to define a plurality of openings 2002 in the second dielectric structure 120 over the first and second conductive structures 114, 116. In some embodiments, the patterning process comprises: forming a patterned masking layer (not shown) over the second dielectric structure 120; performing an etching process (e.g., ion beam etching process, a reactive-ion etching process, wet etch process, etc.) according to the patterned masking layer; and performing a removal process to remove the patterned masking layer. The patterning process may be performed within a processing chamber at a temperature within a range of about 20 degrees Celsius to about 100 degrees Celsius or some other suitable value.

As shown in cross-sectional view 2100 of FIG. 21, a first contact electrode 124 and a second contact electrode 126 are formed over the first and second conductive structures 114, 116. A process for forming the first and second contact electrodes 124, 126 may include: depositing (e.g., by an E-Gun process, sputtering, electroplating, screen printing, etc.) a conductive material layer over the second dielectric structure 120 and filling the openings (2002 of FIG. 20); and patterning (e.g., by a lift-off process, an ion beam etching process, a reactive-ion etching process, a wet etch process, etc.) the conductive material layer to define the first and second contact electrodes 124, 126. The deposition and/or patterning of the conductive material layer may be performed at a temperature within a range of about 20 degrees Celsius to about 100 degrees Celsius or some other suitable value. In some embodiments, the conductive material layer may, for example, be or comprise platinum, gold, zinc, copper, aluminum, titanium, titanium nitride, tungsten titanium, ruthenium, some other conductive material, or any combination of the foregoing. Further, the first and second contact electrodes 124, 126 may each have a thickness within a range of about 20 nm to about 500 nm or some other suitable value.

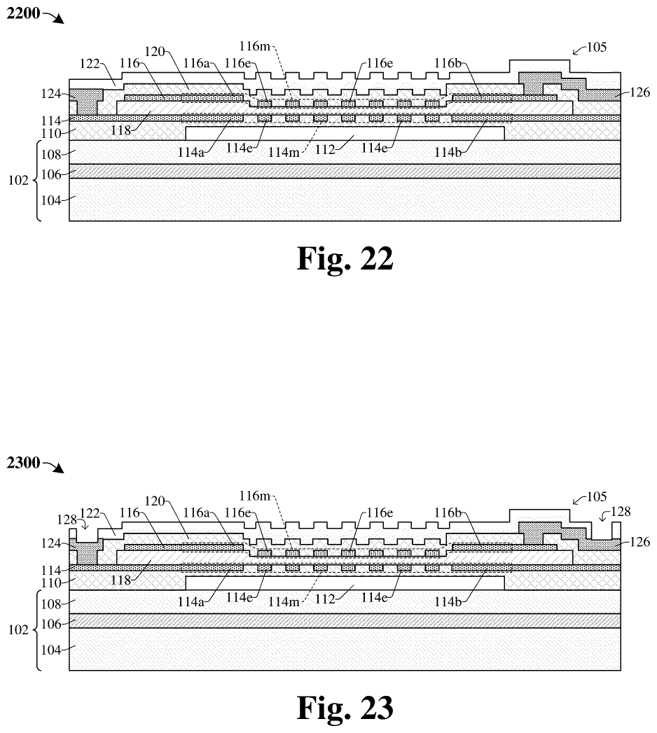

As shown in cross-sectional view 2200 of FIG. 22, a passivation layer 122 is formed over the second dielectric structure 120. The passivation layer 122 is formed over the second dielectric structure 120 by, for example, CVD, ALD, PVD, or some other suitable growth or deposition process. The passivation layer 122 may, for example, be or comprise silicon oxide, aluminum oxide, tantalum oxide, hafnium oxide, silicon nitride, yttrium oxide, zirconium oxide, titanium oxide, lanthanum oxide, some other dielectric material, or any combination of the foregoing. In some embodiments, the passivation layer 122 has a thickness within a range of about 100 nm to about 10,000 nm or some other suitable value.

As shown in cross-sectional view 2300 of FIG. 23, a patterning process is performed on the passivation layer 122 to define a plurality of contact openings 128 in the passivation layer 122 over the first and second contact electrodes 124, 126. In some embodiments, the patterning process comprises: forming a patterned masking layer (not shown) over the passivation layer 122; performing an etching process (e.g., ion beam etching process, a reactive-ion etching process, wet etch process, etc.) according to the patterned masking layer; and performing a removal process to remove the patterned masking layer. The patterning process may be performed within a processing chamber at a temperature within a range of about 20 degrees Celsius to about 100 degrees Celsius or some other suitable value.

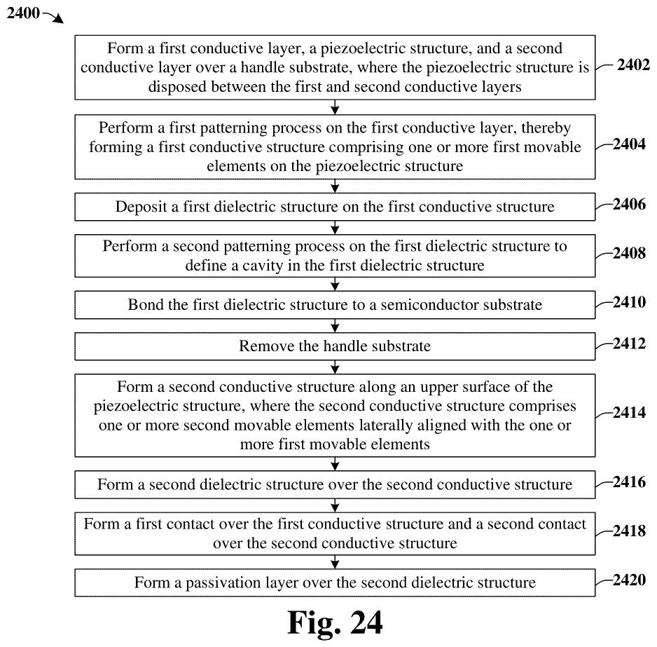

FIG. 24 illustrates a method 2400 of some embodiments of forming a piezoelectric device comprising a piezoelectric structure disposed between patterned conductive structures. Although the method 2400 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 2402, a first conductive layer, a piezoelectric structure, and a second conductive layer are formed over a handle substrate, where the piezoelectric structure is disposed between the first and second conductive layers. FIGS. 8A and 8B illustrate cross-sectional view 800a and top view 800b corresponding to various embodiments of act 2402.

At act 2404, a first patterning process is performed on the first conductive layer, thereby forming a first conductive structure comprising one or more first movable elements on the piezoelectric structure. FIGS. 9A and 9B illustrate cross-sectional view 900a and top view 900b corresponding to various embodiments of act 2404.

At act 2406, a first dielectric structure is deposited on the first conductive structure. FIG. 10 illustrates cross-sectional view 1000 corresponding to various embodiments of act 2406.

At act 2408, a second patterning process is performed on the first dielectric structure, thereby defining a cavity in the first dielectric structure. FIG. 11 illustrates cross-sectional view 1100 corresponding to various embodiments of act 2408.

At act 2410, the first dielectric structure is bonded to a semiconductor substrate. FIG. 12 illustrates cross-sectional view 1200 corresponding to various embodiments of act 2410.

At act 2412, the handle substrate is removed. FIG. 13 illustrates cross-sectional view 1300 corresponding to various embodiments of act 2412.

At act 2414, a second conductive structure is formed along an upper surface of the piezoelectric structure, where the second conductive structure comprises one or more second movable elements laterally aligned with the one or more first movable elements. FIGS. 16-17B illustrate various views 1600-1700b corresponding to various embodiments of act 2414.

At act 2416, a second dielectric structure is formed over the second conductive structure. FIG. 19 illustrates cross-sectional view 1900 corresponding to various embodiments of act 2416.

At act 2418, a first contact is formed over the first conductive structure and a second contact is formed over the second conductive structure. FIGS. 20 and 21 illustrate cross-sectional views 2000 and 2100 corresponding to various embodiments of act 2418.

At act 2420, a passivation layer is formed over the second dielectric structure. FIG. 22 illustrates cross-sectional view 2200 corresponding to various embodiments of act 2420.

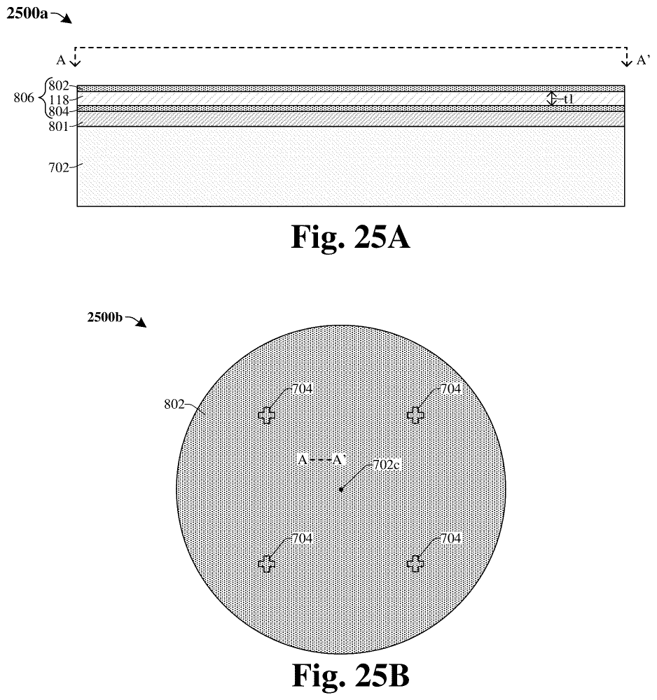

FIGS. 25A-41 illustrate various views 2500a-4100 of some embodiments of a second method of forming a piezoelectric device comprising a piezoelectric structure disposed between patterned conductive structures. Although the various views 2500a-4100 shown in FIGS. 25A-41 are described with reference to a second method, it will be appreciated that the structures shown in FIGS. 25A-41 are not limited to the second method but rather may stand alone separate of the second method. Furthermore, although FIGS. 25A-41 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

As shown in cross-sectional view 2500a and top view 2500b respectively of FIGS. 25A and 25B, a handle substrate 702 is provided and an insulator structure 801 and a stack of piezoelectric layers 806 are formed on the handle substrate 702. Further, a plurality of alignment marks 704 are disposed on the handle substrate 702. The stack of piezoelectric layers 806 comprises a piezoelectric structure 118 disposed between a first conductive layer 802 and a second conductive layer 804. The insulator structure 801, the stack of piezoelectric layers 806, and/or the alignment marks 704 may be formed over and/or on the handle substrate 702 as illustrated and/or described in FIGS. 8A and 8B.

FIG. 25B illustrates the top view 2500b corresponding to some embodiments of the cross-sectional view 2500a taken along the line A-A′ of FIG. 25A. As illustrated in FIG. 25B, the alignment marks 704 each have a cross shape. However, it will be appreciated that the alignment marks 704 may have other shapes and/or sizes and/or may be located in other regions of the handle substrate 702. In yet further embodiments, the alignment marks 704 are present and/or detectable in the stack of piezoelectric layers (806 of FIG. 25A) and/or the insulator structure (801 of FIG. 25A).

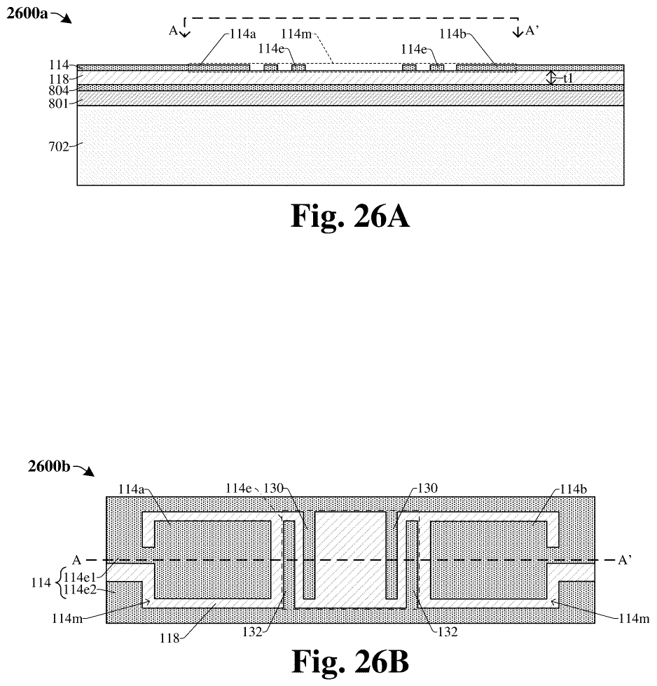

As shown in cross-sectional view 2600a of FIG. 26A and top view 2600b of FIG. 26B, a first patterning process is performed on the first conductive layer (802 of FIG. 25A) to form a first conductive structure 114 comprising one or more first movable elements 114m on the piezoelectric structure 118. In various embodiments, the first patterning process forms the one or more first movable elements 114m in the first conductive structure 114, where the one or more first movable elements 114m comprise a first electrode plate 114a, a second electrode plate 114b, and a plurality of elongated electrode segments 114e disposed laterally between the first and second electrode plates 114a, 114b. In some embodiments, the first patterning process comprises: forming a patterned masking layer (not shown) over the first conductive layer (802 of FIG. 25A); performing an etching process according to the patterned masking layer, thereby defining the first conductive structure 114 and the one or more first movable elements 114m; and performing a removal process to remove the patterned masking layer. Further, the first patterning process may be performed within a processing chamber at a temperature within a range of about 20 degrees Celsius to about 100 degrees Celsius or some other suitable value. The etching process, may for example, be or comprise an ion beam etching process, a reactive-ion etching process, a wet etch process, some other suitable etching process, or any combination of the foregoing. In yet further embodiments, the patterned masking layer (not shown) and/or the etching process may be aligned by virtue of at least the plurality of alignment marks (704 of FIG. 25B). In further embodiments, the first patterning process includes performing a lift off patterning process or some other suitable patterning process.

FIG. 26B illustrates the top view 2600b corresponding to some embodiments of the cross-sectional view 2600a taken along the line A-A′ of FIG. 26A. FIG. 26B illustrates a layout of the first conductive structure 114 after the first patterning process. In various embodiments, the first conductive structure comprises a first electrode structure 114e1 and a second electrode structure 114e2. In some instances, a discontinuity is present in the first conductive structure 114 in order to electrically isolate the first electrode structure 114e1 from the second electrode structure 114e2, where the first patterning process forms the discontinuity in the first conductive structure 114. The first electrode structure 114e1 comprises the first and second electrode plates 114a, 114b and a first subset 130 of the elongated electrode segments 114e. The second electrode structure 114e2 comprises a second subset 132 of the elongated electrode segments 114e.

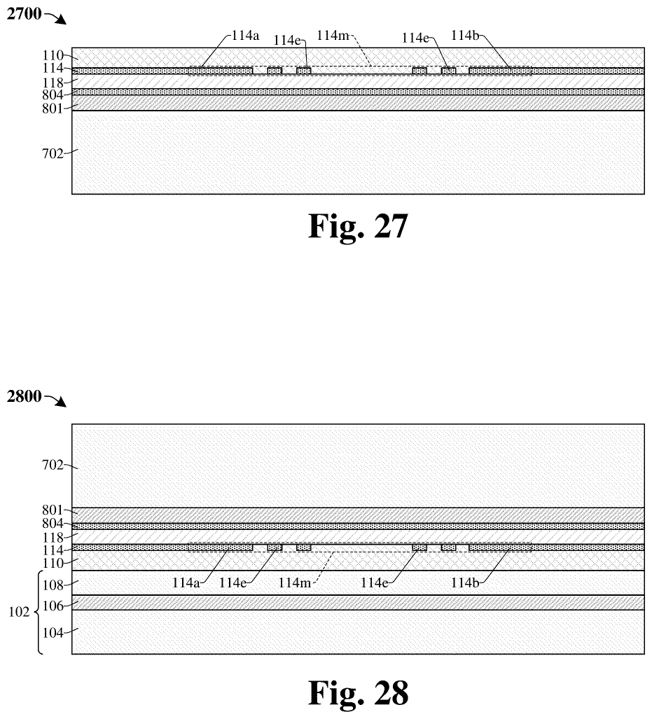

As shown in cross-sectional view 2700 of FIG. 27, a first dielectric structure 110 is formed over the first conductive structure 114 and the piezoelectric structure 118. The first dielectric structure 110 may be formed on the first conductive structure 114 by, for example, CVD, ALD, PVD, or some other suitable growth or deposition process. In some embodiments, the first dielectric structure 110 has a thickness within a range of about 100 nm to about 10,000 nm or some other suitable value. In yet further embodiments, the first dielectric structure 110 may comprise a multi-layer dielectric stack (not shown) comprising two or more dielectric layers having different materials from one another.

As shown in cross-sectional view 2800 of FIG. 28, a bonding process is performed to bond the first dielectric structure 110 to a semiconductor substrate 102. In various embodiments, the bonding process includes performing a fusion bonding process or some other suitable bonding process. In further embodiments, the bonding process includes exposing the first dielectric structure 110 and the semiconductor substrate 102 to a temperature within a range of about 20 degrees Celsius to about 100 degrees Celsius or some other suitable value. The semiconductor substrate 102 may, for example, be or comprise a bulk semiconductor substrate such as a bulk silicon substrate, a silicon-on-insulator (SOI) substrate, some other similar substrate, or any combination of the foregoing. In some embodiments, the semiconductor substrate 102 comprises a first substrate 104, an insulator layer 106, and a second substrate 108.

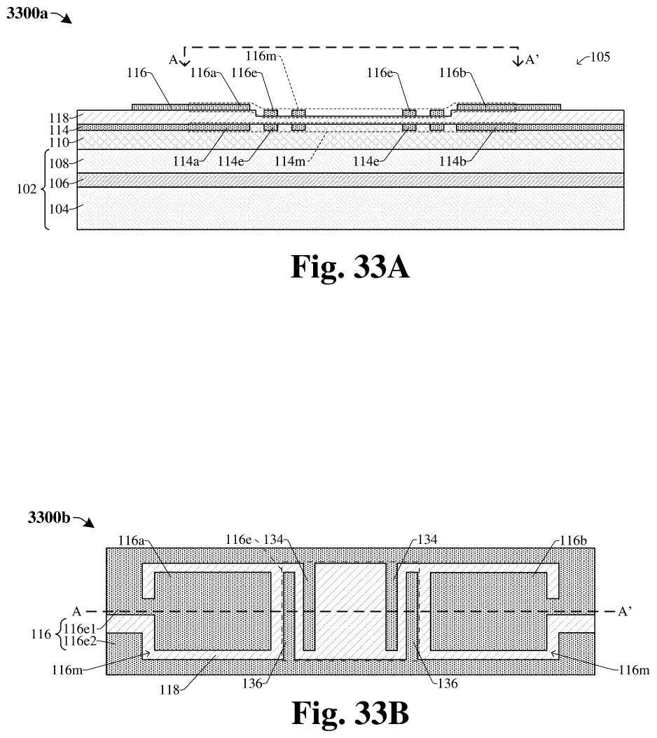

In some embodiments, patterned structures are not disposed on the semiconductor substrate 102 such that an alignment process may not be performed before and/or during the bonding process to align features of the first conductive structure 114 with patterned features disposed on the semiconductor substrate 102. As a result, fabrication costs and complexity are reduced. Further, misalignment between the one or more first movable elements 114m and/or other patterned features (e.g., the one or more second movable elements 116m of FIGS. 33A and 33B) is reduced.

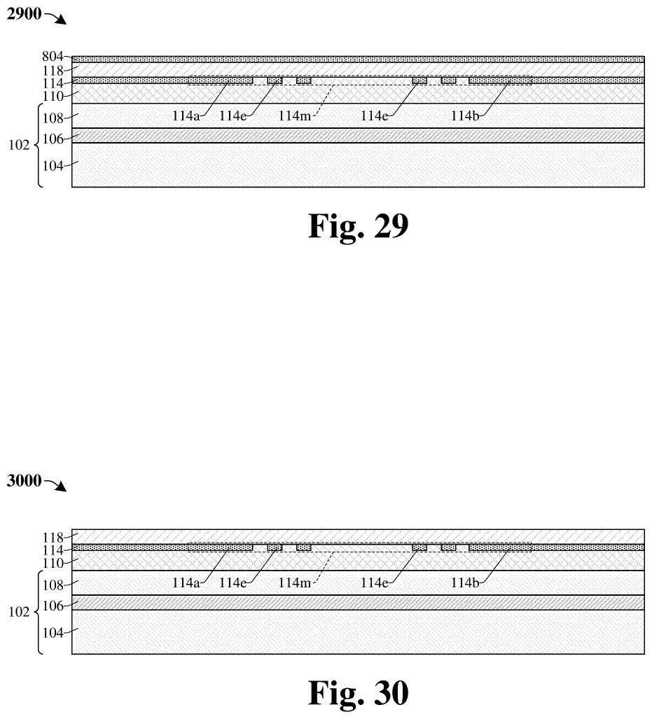

As shown in cross-sectional view 2900 of FIG. 29, a removal process is performed to remove the handle substrate (702 of FIG. 28) and the insulator structure (801 of FIG. 28). The removal process may, for example, include: removing the handle substrate (702 of FIG. 28) by a CMP process, a mechanical grinding process, or the like, and removing the insulator structure (801 of FIG. 28) by an ion beam etching process, a reactive-ion etching process, a wet etch process, or the like. The removal process may be performed at a temperature within a range of about 20 degrees Celsius to about 100 degrees Celsius or some other suitable value.

As shown in cross-sectional view 3000 of FIG. 30, an etching process is performed to remove the second conductive layer (804 of FIG. 29) and expose an upper surface of the piezoelectric structure 118. In various embodiments, the etching process includes performing an ion beam etching process, a reactive-ion etching process, a wet etch process, or the like. The etching process may be performed at a temperature within a range of about 20 degrees Celsius to about 100 degrees Celsius or some other suitable value.

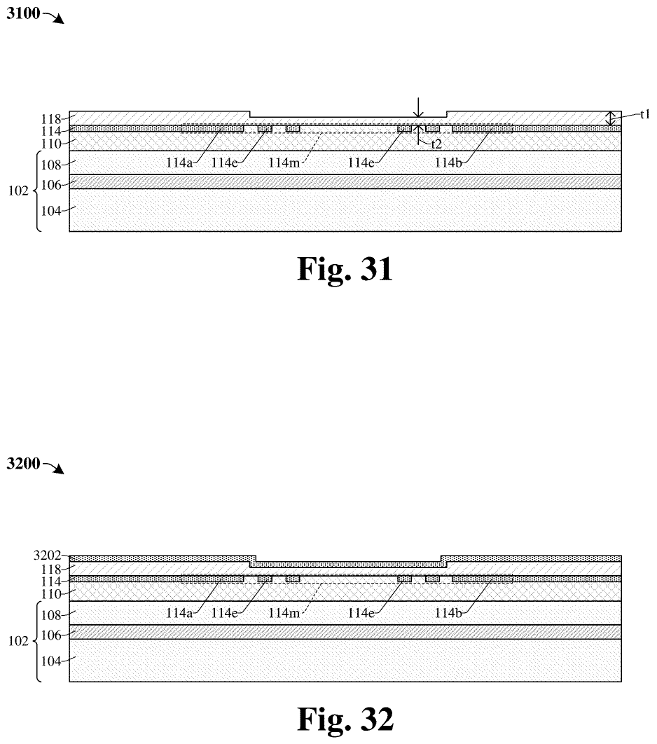

As shown in cross-sectional view 3100 of FIG. 31 a patterning process is performed on the piezoelectric structure 118 such that the piezoelectric structure 118 has a second thickness t2 within a middle region of the piezoelectric structure 118. In some embodiments, the second thickness t2 is less than the first thickness t1. For example, the second thickness t2 may be within a range of about 30% to about 80% of the first thickness t1. In some embodiments, the patterning process comprises: forming a patterned masking layer (not shown) over the piezoelectric structure 118; performing an etching process according to the patterned masking layer, thereby defining the second thickness t2 within the middle region of the piezoelectric structure 118; and performing a removal process to remove the patterned masking layer. The patterning process may be performed within a processing chamber at a temperature within a range of about 20 degrees Celsius to about 100 degrees Celsius or some other suitable value. The etching process, may for example, be or comprise an ion beam etching process, a reactive-ion etching process, a wet etch process, some other suitable etching process, or any combination of the foregoing.

As shown in cross-sectional view 3200 of FIG. 32, a conductive layer 3202 is formed on the piezoelectric structure 118. The conductive layer 3202 may be formed on the piezoelectric structure 118 by, for example, an E-Gun process, sputtering, electroplating, screen printing, PVD, or some other suitable growth or deposition process. The conductive layer 3202 may, for example, be or comprise platinum, gold, zinc, copper, ruthenium, rhodium, palladium, osmium, iridium, silver, tungsten, tin, some other conductive material, or any combination of the foregoing. The conductive layer 3202 may have a thickness within a range of about 20 nm to about 500 nm or some other suitable value.

As shown in cross-sectional view 3300a of FIG. 33A and top view 3300b of FIG. 33B, a patterning process is performed on the conductive layer (3202 of FIG. 32), thereby forming a second conductive structure 116 comprising one or more second movable elements 116m along the upper surface of the piezoelectric structure 118 and a piezoelectric device 105. In some embodiments, the one or more second movable elements 116m comprise a first electrode plate 116a, a second electrode plate 116b, and a plurality of elongated electrode segments 116e disposed laterally between the first and second electrode plates 116a, 116b.

In some embodiments, the patterning process comprises: forming a patterned masking layer (not shown) over the conductive layer (3202 of FIG. 32); performing an etching process according to the patterned masking layer, thereby defining the second conductive structure 116 and the one or more second movable elements 116m; and performing a removal process to remove the patterned masking layer. Further, the patterning process may be performed within a processing chamber at a temperature within a range of about 20 degrees Celsius to about 100 degrees Celsius or some other suitable value. The etching process, may for example, be or comprise an ion beam etching process, a reactive-ion etching process, a wet etch process, some other suitable etching process, or any combination of the foregoing. In yet further embodiments, the patterned masking layer (not shown) and/or the etching process may be aligned by virtue of at least the plurality of alignment marks (704 of FIG. 25B), such that the one or more second movable elements 116m of the second conductive structure 116 are aligned according to the plurality of alignment marks (704 of FIG. 25B). As a result, the one or more second movable elements 116m are aligned with the one or more first movable elements 114m. In further embodiments, the patterning process includes performing a lift off patterning process or some other suitable patterning process.

FIG. 33B illustrates the top view 3300b corresponding to some embodiments of the cross-sectional view 3300a taken along the line A-A′ of FIG. 33A. FIG. 33B illustrates a layout of the second conductive structure 116 after the patterning process. In various embodiments, the second conductive structure 116 comprises a first electrode structure 116e1 and a second electrode structure 116e2. In some instances, a discontinuity is present in the second conductive structure 116 in order to electrically isolate the first electrode structure 116e1 from the second electrode structure 116e2, where the patterning process forms the discontinuity in the second conductive structure 116. The first electrode structure 116e1 comprises the first and second electrode plates 116a, 116b and a first subset 134 of the elongated electrode segments 116e. The second electrode structure 116e2 comprises a second subset 136 of the elongated electrode segments 116e.

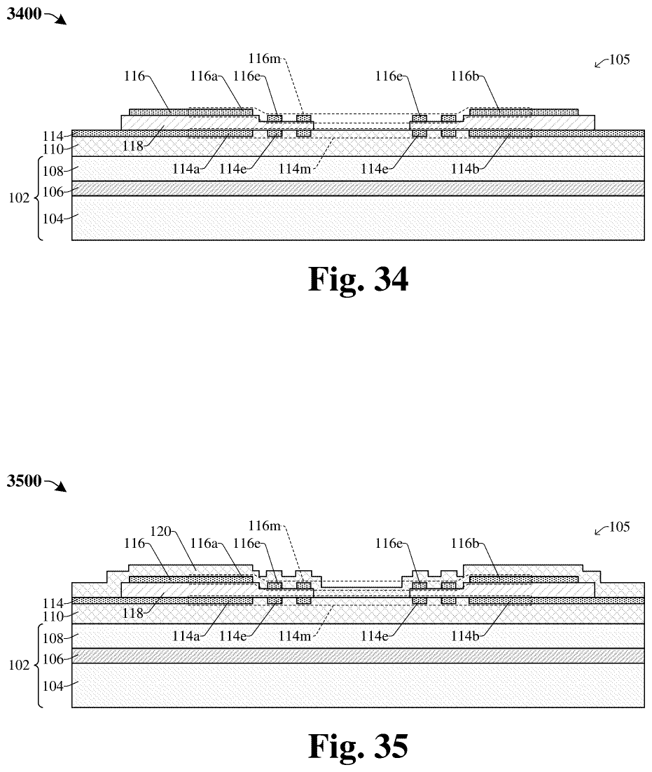

As shown in cross-sectional view 3400 of FIG. 34, a patterning process is performed on the piezoelectric structure 118 to remove the piezoelectric structure 118 from over outer regions of the first conductive structure 114 and from over a middle region of the first dielectric structure 110. In some embodiments, the patterning process comprises: forming a patterned masking layer (not shown) over the piezoelectric structure 118; performing an etching process according to the patterned masking layer; and performing a removal process to remove the patterned masking layer. The patterning process may be performed within a processing chamber at a temperature within a range of about 20 degrees Celsius to about 100 degrees Celsius or some other suitable value. The etching process, may for example, be or comprise an ion beam etching process, a reactive-ion etching process, a wet etch process, some other suitable etching process, or any combination of the foregoing.

As shown in cross-sectional view 3500 of FIG. 35, a second dielectric structure 120 is formed over the piezoelectric device 105. The second dielectric structure 120 may be formed by, for example, CVD, ALD, PVD, or some other suitable growth or deposition process. In some embodiments, the second dielectric structure 120 has a thickness within a range of about 100 nm to about 10,000 nm or some other suitable value. In yet further embodiments, the second dielectric structure 120 may comprise a multi-layer dielectric stack (not shown) comprising two or more dielectric layers having different materials from one another.

As shown in cross-sectional view 3600 of FIG. 36, a patterning process is performed on the second dielectric structure 120 to define a plurality of openings 3602 in the second dielectric structure 120 over the first and second conductive structures 114, 116. In some embodiments, the patterning process comprises: forming a patterned masking layer (not shown) over the second dielectric structure 120; performing an etching process (e.g., ion beam etching process, a reactive-ion etching process, wet etch process, etc.) according to the patterned masking layer; and performing a removal process to remove the patterned masking layer. The patterning process may be performed within a processing chamber at a temperature within a range of about 20 degrees Celsius to about 100 degrees Celsius or some other suitable value.

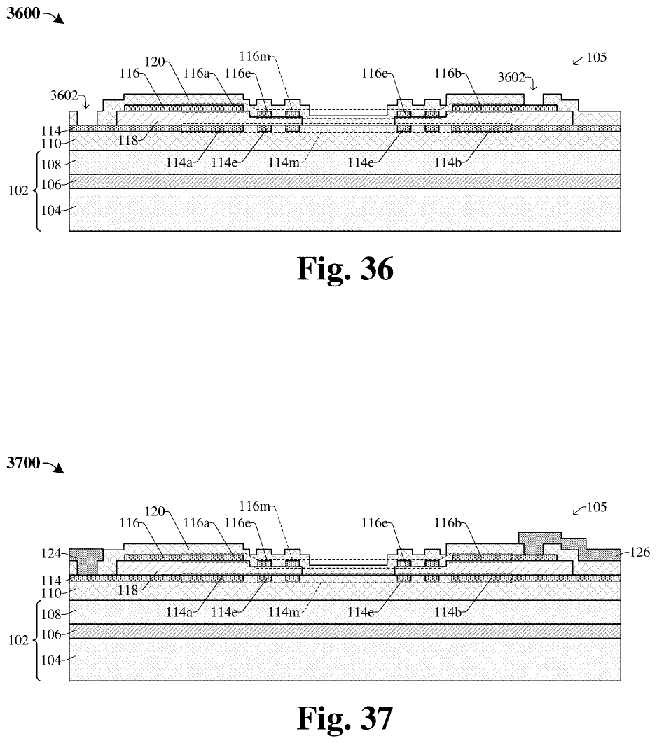

As shown in cross-sectional view 3700 of FIG. 37, a first contact electrode 124 and a second contact electrode 126 are formed over the first and second conductive structures 114, 116. A process for forming the first and second contact electrodes 124, 126 may include: depositing (e.g., by an e-gun process, sputtering, electroplating, screen printing, etc.) a conductive material layer over the second dielectric structure 120 and filling the openings (3602 of FIG. 36); and patterning (e.g., by a lift-off process, an ion beam etching process, a reactive-ion etching process, a wet etch process, etc.) the conductive material layer to define the first and second contact electrodes 124, 126. The deposition and/or patterning of the conductive material layer may be performed at a temperature within a range of about 20 degrees Celsius to about 100 degrees Celsius or some other suitable value. In some embodiments, the conductive material layer may, for example, be or comprise platinum, gold, zinc, copper, aluminum, titanium, titanium nitride, tungsten titanium, ruthenium, some other conductive material, or any combination of the foregoing. Further, the first and second contact electrodes 124, 126 may each have a thickness within a range of about 20 nm to about 500 nm or some other suitable value.

As shown in cross-sectional view 3800 of FIG. 38, a passivation layer 122 is formed over the second dielectric structure 120. The passivation layer 122 is formed over the second dielectric structure 120 by, for example, CVD, ALD, PVD, or some other suitable growth or deposition process. In some embodiments, the passivation layer 122 has a thickness within a range of about 100 nm to about 10,000 nm or some other suitable value.

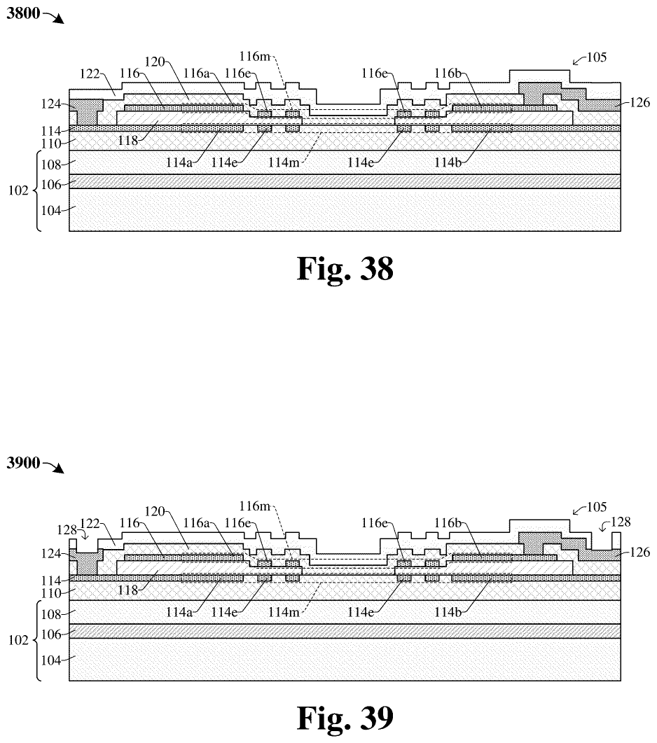

As shown in cross-sectional view 3900 of FIG. 39, a patterning process is performed on the passivation layer 122 to define a plurality of contact openings 128 in the passivation layer 122 over the first and second contact electrodes 124, 126. In some embodiments, the patterning process comprises: forming a patterned masking layer (not shown) over the passivation layer 122; performing an etching process (e.g., ion beam etching process, a reactive-ion etching process, wet etch process, etc.) according to the patterned masking layer; and performing a removal process to remove the patterned masking layer. The patterning process may be performed within a processing chamber at a temperature within a range of about 20 degrees Celsius to about 100 degrees Celsius or some other suitable value.

As shown in cross-sectional view 4000 of FIG. 40, a patterning process is performed on the passivation layer 122, the first dielectric structure 110, and the second dielectric structure 120 to define an opening 406 extending through a middle region of the piezoelectric device 105. In some embodiments, the patterning process removals at least a portion of the first conductive structure 114, the second conductive structure 116, and/or the piezoelectric structure 118. In some embodiments, the patterning process comprises: forming a patterned masking layer (not shown) over the passivation layer 122, performing an etching process (e.g., ion beam etching process, a reactive-ion etching process, wet etch process, etc.) according to the patterned masking layer; and performing a removal process to remove the patterned masking layer. The patterning process may be performed within a processing chamber at a temperature within a range of about 20 degrees Celsius to about 100 degrees Celsius or some other suitable value.

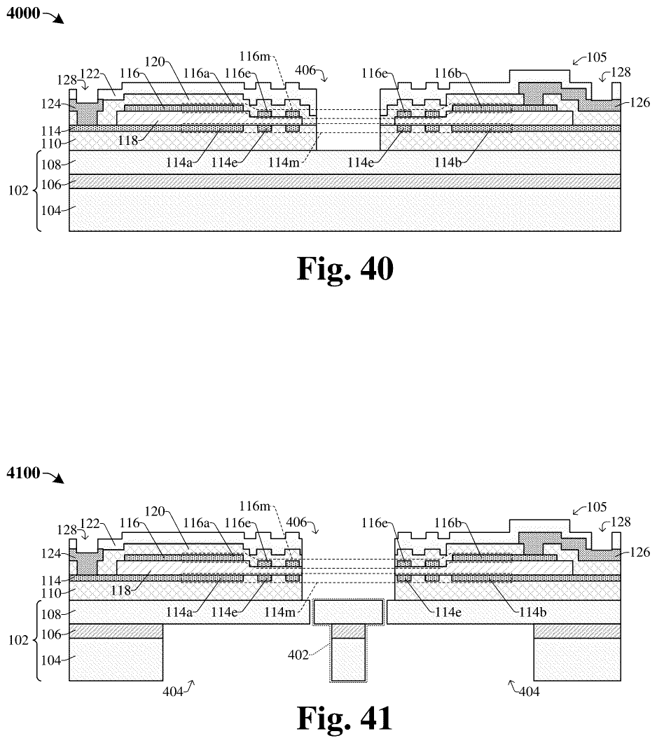

As shown in cross-sectional view 4100 of FIG. 41, an etching process is performed on the piezoelectric device 105, the first and second dielectric structures 110, 120, the passivation layer 122, and the semiconductor substrate 102. The etching process expands the opening 406, forms a lower movable element 402 in the semiconductor substrate 102, and defines lower openings 404 in the semiconductor substrate 102 under the first dielectric structure 110. In some embodiments, the etching process includes a deep reactive-ion etching process and/or a reactive-ion etching process, or the like. Further, the etching process may be performed at a temperature within a range of about 20 degrees Celsius to about 100 degrees Celsius or some other suitable value.

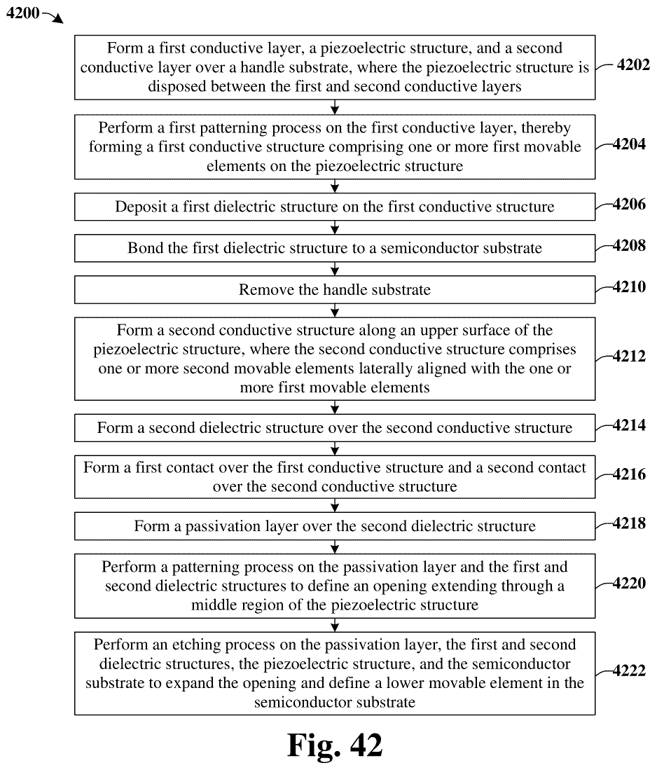

FIG. 42 illustrates a method 4200 of some other embodiments of forming a piezoelectric device comprising a piezoelectric structure disposed between patterned conductive structures. Although the method 4200 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 4202, a first conductive layer, a piezoelectric structure, and a second conductive layer are formed over a handle substrate, where the piezoelectric structure is disposed between the first and second conductive layers. FIGS. 25A and 25B illustrate cross-sectional view 2500a and top view 2500b corresponding to various embodiments of act 4202.

At act 4204, a first patterning process is performed on the first conductive layer, thereby forming a first conductive structure comprising one or more first movable elements on the piezoelectric structure. FIGS. 26A and 26B illustrate cross-sectional view 900a and top view 900b corresponding to various embodiments of act 4204.

At act 4206, a first dielectric structure is deposited on the first conductive structure. FIG. 27 illustrates cross-sectional view 2700 corresponding to various embodiments of act 4206.

At act 4208, the first dielectric structure is bonded to a semiconductor substrate. FIG. 28 illustrates cross-sectional view 2800 corresponding to various embodiments of act 4208.

At act 4210, the handle substrate is removed. FIG. 29 illustrates cross-sectional view 2900 corresponding to various embodiments of act 4210.

At act 4212, a second conductive structure is formed along an upper surface of the piezoelectric structure, where the second conductive structure comprises one or more second movable elements laterally aligned with the one or more first movable elements. FIGS. 32-33B illustrate various views 3200-3300b corresponding to various embodiments of act 4212.

At act 4214, a second dielectric structure is formed over the second conductive structure. FIG. 35 illustrates cross-sectional view 3500 corresponding to various embodiments of act 4214.

At act 4216, a first contact is formed over the first conductive structure and a second contact is formed over the second conductive structure. FIGS. 36 and 37 illustrate cross-sectional views 3600 and 3700 corresponding to various embodiments of act 4216.

At act 4218, a passivation layer is formed over the second dielectric structure. FIG. 38 illustrates cross-sectional view 3800 corresponding to various embodiments of act 4218.

At act 4220, a patterning process is performed on the passivation layer and the first and second dielectric structures to define an opening extending though a middle region of the piezoelectric structure. FIG. 40 illustrates cross-sectional view 4000 corresponding to various embodiments of act 4220.

At act 4222, an etching process is performed on the passivation layer, the first and second dielectric structures, the piezoelectric structure, and the semiconductor substrate to expand the opening and define a lower movable element in the semiconductor substrate. FIG. 41 illustrates cross-sectional view 4100 corresponding to various embodiments of act 4222.

Accordingly, in some embodiments, the present disclosure relates to a piezoelectric device comprising a piezoelectric structure disposed between a first conductive structure and a second conductive structure, where the first and second conductive structures respectively comprise one or more movable elements.

In some embodiments, the present application provides a piezoelectric device including a piezoelectric structure overlying a substrate; a first conductive structure disposed on a lower surface of the piezoelectric structure, wherein the first conductive structure comprises one or more first movable elements directly contacting the piezoelectric structure; and a second conductive structure disposed on an upper surface of the piezoelectric structure, wherein the second conductive structure comprises one or more second movable elements directly contacting the piezoelectric structure, wherein the one or more second movable elements directly overlie the one or more first movable elements.

In some embodiments, the present application provides a piezoelectric device including: a first dielectric structure disposed on a substrate; a piezoelectric structure disposed on the first dielectric structure; a first conductive structure disposed on a lower surface of the piezoelectric structure, wherein the first conductive structure comprises a first electrode plate and a first plurality of elongated electrode segments laterally adjacent to the first electrode plate; and a second conductive structure disposed on an upper surface of the piezoelectric structure, wherein the second conductive structure comprises a second electrode plate and a second plurality of elongated electrode segments laterally adjacent to the second electrode plate, wherein opposing sidewalls of the first plurality of elongated electrode segments are aligned with opposing sidewalls of the second plurality of elongated electrode segments.

In some embodiments, the present application provides a method for forming a piezoelectric device, the method includes: forming a stack of piezoelectric layers over a first substrate, wherein the stack of piezoelectric layers comprises a first conductive layer disposed on a piezoelectric structure; performing a first patterning process on the first conductive layer to form a first conductive structure comprising one or more first movable elements on the piezoelectric structure; forming a first dielectric structure on the first conductive structure; performing a bonding process to bond the first dielectric structure to a second substrate; and forming a second conductive structure on an upper surface of the piezoelectric structure, wherein the second conductive structure comprises one or more second movable elements, wherein a layout of the one or more first movable elements is the same as a layout of the one or more second movable elements.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A piezoelectric device comprising:
a piezoelectric structure overlying a substrate;
a first conductive structure disposed on a lower surface of the piezoelectric structure, wherein the first conductive structure comprises one or more first movable elements directly contacting the piezoelectric structure; and
a second conductive structure disposed on an upper surface of the piezoelectric structure, wherein the second conductive structure comprises one or more second movable elements directly contacting the piezoelectric structure, wherein the one or more second movable elements directly overlie the one or more first movable elements.

2. The piezoelectric device of claim 1, wherein a layout of the one or more first movable elements is the same as a layout of the one or more second movable elements.

3. The piezoelectric device of claim 1, wherein the one or more first movable elements comprises a first electrode plate, a second electrode plate, and a first plurality of elongated electrode segments disposed laterally between the first and second electrode plates, wherein the one or more second movable elements comprises a third electrode plate, a fourth electrode plate, and a second plurality of elongated electrode segments disposed laterally between the third and fourth electrode plates.

4. The piezoelectric device of claim 3, wherein opposing sidewalls of the first electrode plate are aligned with opposing sidewalls of the third electrode plate.

5. The piezoelectric device of claim 3, wherein a width of the first electrode plate is greater than a width of an individual elongated electrode segment in the first plurality of elongated electrode segments, and wherein a length of the first electrode plate is less than a length of the individual elongated electrode segment.

6. The piezoelectric device of claim 3, wherein the first plurality of elongated electrode segments comprises a subset of first elongated segments disposed alternatingly with a subset of second elongated segments, wherein the subset of first elongated segment, the first electrode plate, and the second electrode plate are part of a first continuous electrode structure and the subset of second elongated segments is part of a second continuous electrode structure discrete from the first continuous electrode structure.

7. The piezoelectric device of claim 1, further comprising:
a first dielectric structure disposed between the piezoelectric structure and the substrate, wherein the first dielectric structure comprises opposing sidewalls defining a cavity, wherein the one or more first movable elements and the one or more second movable elements at least partially directly overlie the cavity.

8. The piezoelectric device of claim 1, wherein the piezoelectric structure has a first thickness disposed at a peripheral region of the first conductive structure and a second thickness disposed at a middle region of the first conductive structure, wherein the first thickness is greater than the second thickness.

9. The piezoelectric device of claim 1, wherein the piezoelectric structure and the first and second conductive structures define an opening extending through a middle region of the piezoelectric device, wherein the substrate comprises a proof mass suspended under the opening.

10. A piezoelectric device comprising:
a first dielectric structure disposed on a substrate;
a piezoelectric structure disposed on the first dielectric structure;
a first conductive structure disposed on a lower surface of the piezoelectric structure, wherein the first conductive structure comprises a first electrode plate and a first plurality of elongated electrode segments laterally adjacent to the first electrode plate; and
a second conductive structure disposed on an upper surface of the piezoelectric structure, wherein the second conductive structure comprises a second electrode plate and a second plurality of elongated electrode segments laterally adjacent to the second electrode plate, wherein opposing sidewalls of the first plurality of elongated electrode segments are aligned with opposing sidewalls of the second plurality of elongated electrode segments.

11. The piezoelectric device of claim 10, wherein a top surface of the second electrode plate is above a top surface of the second plurality of elongated electrode segments.

12. The piezoelectric device of claim 10, wherein the piezoelectric structure has a first thickness between the first electrode plate and the second electrode plate, and wherein the piezoelectric structure has a second thickness between the first plurality of elongated electrode segments and the second plurality of elongated electrode segments, wherein the first thickness is different from the second thickness.

13. The piezoelectric device of claim 10, wherein sidewalls of the first dielectric structure and sidewalls of the piezoelectric structure define an opening extending through a middle region of the piezoelectric device, wherein the first plurality of elongated electrode segments comprises a first elongated electrode segment and a second elongated electrode segment, wherein the opening is disposed laterally between the first elongated electrode segment and the second elongated electrode segment.

14. The piezoelectric device of claim 13, wherein the substrate comprises a lower movable element suspended under the opening and spaced laterally between the first elongated electrode segment and the second elongated electrode segment.

15. The piezoelectric device of claim 10, wherein a thickness of the first conductive structure is less than a thickness of the piezoelectric structure.

16. A piezoelectric device comprising:
a first conductive structure over a substrate and comprising a first electrode plate and a first plurality of elongated electrode segments, wherein the first electrode plate extends in a first direction and the first plurality of elongated electrode segments extend in a second direction substantially orthogonal to the first direction, wherein a width of the first electrode plate in the first direction is greater than a width of an individual elongated electrode segment of the first plurality of elongated electrode segments in the first direction, wherein a length of the first electrode plate in the second direction is less than a length of the individual elongated electrode segment in the second direction; and
a piezoelectric structure over the first conductive structure and contacting the first electrode plate and the first plurality of elongated electrode segments; and
a second conductive structure over the piezoelectric structure and comprising a second electrode plate and a second plurality of elongated electrode segments, wherein the second electrode plate overlies the first electrode plate and the second plurality of elongated electrode segments overlie the first plurality of electrode segments.

17. The piezoelectric device of claim 16, wherein a top surface of the first electrode plate is aligned with a top surface of the first plurality of elongated electrode segments, wherein a top surface of the second electrode plate is above a top surface of the second plurality of elongated electrode segments.

18. The piezoelectric device of claim 16, further comprising:
a first dielectric structure between the first conductive structure and the substrate, wherein the first dielectric structure contacts sidewalls of the first electrode plate and sidewalls of one or more of the first plurality of elongated electrode segments, wherein a top surface of the first dielectric structure is aligned with a top surface of the first electrode plate; and
a second dielectric structure over the piezoelectric structure and the second conductive structure, wherein the second dielectric structure contacts sidewalls of the second electrode plate and sidewalls of one or more of the second plurality of elongated electrode segments, wherein a lower surface of the second dielectric structure is aligned with a bottom surface of the second electrode plate.

19. The piezoelectric device of claim 16, wherein a distance between adjacent elongated electrode segments in the first plurality of elongated electrode segments is less than the width of the first electrode plate.

20. The piezoelectric device of claim 16, wherein the second plurality of elongated electrode segments are spaced between a pair of inner opposing sidewalls of the piezoelectric structure.
